(19) United States
(12) Patent Application Publication
(10) Pub. No.: US 2019/0304878 A1
(43) Pub. Date: Oct. 3, 2019

(54) ELECTRONIC DEVICE, SUBSTRATE, AND ELECTRONIC COMPONENT

(71) Applicant: FUJITSU LIMITED, Kawasaki-shi (JP)

(72) Inventor: KEIICHI YAMAMOTO, Yokohama (JP)

(73) Assignee: FUJITSU LIMITED, Kawasaki-shi (JP)

(21) Appl. No.: 16/276,681

(22) Filed: Feb. 15, 2019

(30) Foreign Application Priority Data
Mar. 29, 2018 (JP) 2018-064189

(51) Int. Cl. H01L 23/488; H01L 23/00; H01L 23/14

(52) U.S. Cl. CPC H01L 23/488; H01L 23/147; H01L 24/05

(57) ABSTRACT

An electronic device includes a substrate, an electronic component provided in a first area of the substrate, a spacer provided between the substrate and the electronic component so as to come into contact with the substrate and the electronic component, a first bonding element provided between the substrate and the electronic component so as to bond the substrate and the electronic component, a second bonding element provided between the substrate and the electronic component so as to bond the substrate and the electronic component, the second bonding element having a height higher than a height of the first bonding element, and a stress generation source provided outside the first area of the substrate to generate a stress in the first area of the substrate, the stress generation source being located closer to the second bonding element than to the first bonding element.

### CROSS-REFERENCE TO RELATED APPLICATION

This application is based upon and claims the benefit of priority of the prior Japanese Patent Application No. 2018-064189, filed on Mar. 29, 2018, the entire contents of which are incorporated herein by reference.

### FIELD

The embodiments discussed herein are related to an electronic device, a substrate, and an electronic component.

### BACKGROUND

A technology has been known which bonds a substrate and an electronic component facing with each other, using a bonding material such as, for example, a solder provided therebetween. With respect to such a technology, for example, a method of providing a support pattern has been known in which a dummy pattern, a solder resist, and a marking are laminated on a substrate to form a support pattern, and support a plurality of positions of an electronic component to be mounted by the support pattern in order to prevent inclination of the electronic component. In addition, a method of providing a pedestal has been known in which a pedestal is formed with a dummy land, a resist layer, and a silk layer in the area of a substrate which faces a package to be mounted, and by the pedestal, separate the package from the substrate so as to reduce distortion occurring in a solder portion which bonds the package and the substrate to each other. In addition, a method of forming a lifting element has been known in which a dummy land pattern and a solder resist are laminated on a substrate where an electronic component is to be mounted and the electronic component is fixed to an electrode on the substrate using a mounted solder in a state where the electronic component is lifted by the lifting element.

Related techniques are disclosed in, for example, Japanese Laid-open Patent Publication Nos. 05-327163, 2006-032622, and 2013-021486.

### SUMMARY

According to an aspect of the embodiments, an electronic device includes a substrate, an electronic component provided in a first area of the substrate, a spacer provided between the substrate and the electronic component so as to come into contact with the substrate and the electronic component, a first bonding element provided between the substrate and the electronic component so as to bond the substrate and the electronic component, a second bonding element provided between the substrate and the electronic component so as to bond the substrate and the electronic component, the second bonding element having a height higher than a height of the first bonding element, and a stress generation source provided outside the first area of the substrate to generate a stress in the first area of the substrate, the stress generation source being located closer to the second bonding element than to the first bonding element.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are views illustrating examples of an electronic device according to a first embodiment;

FIG. 2 is a view (part 1) illustrating a first example of an electronic device according to a second embodiment;

FIGS. 3A and 3B are views (part 2) illustrating the first example of the electronic device according to the second embodiment;

FIG. 4 is a view (part 1) illustrating a second example of the electronic device according to the second embodiment;

FIGS. 5A and 5B are views (part 2) illustrating the second example of the electronic device according to the second embodiment;

FIG. 6 is a view (part 1) illustrating a first example of an electronic device according to a third embodiment;

FIGS. 7A and 7B are views (part 2) illustrating the first example of the electronic device according to the third embodiment;

FIG. 8 is a view (part 1) illustrating a second example of the electronic device according to the third embodiment;

FIGS. 9A and 9B are views (part 2) illustrating the second example of the electronic device according to the third embodiment;

FIG. 10 is a view illustrating an example of an electronic device according to a fourth embodiment;

FIG. 11 is a view illustrating an example of a method of forming a pedestal according to a fifth embodiment;

FIG. 12 is a view for explaining an example of the height adjustment of the pedestal according to the fifth embodiment;

FIG. 13 is a view for explaining a relationship between the width of a conductor layer and the height of the pedestal according to the fifth embodiment;

FIGS. 14A to 14C are views for explaining another example of the height adjustment of the pedestal according to the fifth embodiment;

FIGS. 15A to 15C are views illustrating a first example of a method of forming an electronic device according to a sixth embodiment;

FIGS. 16A to 16C are views illustrating a second example of the method of forming the electronic device according to the sixth embodiment;

FIGS. 17A and 17B are views illustrating a third example of the method of forming the electronic device according to the sixth embodiment;

FIG. 18 is a view (part 1) illustrating an example of an electronic device according to a seventh embodiment;

FIGS. 19A and 19B are views (part 2) illustrating the example of the electronic device according to the seventh embodiment;

FIGS. 20A to 20C are views illustrating an example of a method of forming an electronic device according to an eighth embodiment; and

FIG. 21 is a view for explaining an electronic apparatus according to a ninth embodiment.

### DESCRIPTION OF EMBODIMENTS

According to the technology as described above, a certain bonding height is secured between a substrate and an electronic component which are bonded to each other using a bonding material such as, for example, a solder. However, when a stress generation source which generates stress in the mounting area for the electronic component, for example, a fastening portion which fastens the substrate to another component with a screw, is present on the substrate, a difference in the stress in a group of bonding elements in the mounting area may occur due to a difference in the distance to the stress generation source. Therefore, among the group of bonding elements which bond the substrate and the electronic component to each other, some bonding elements which are relatively close to the stress generation source and generate relatively large stress may cause a bonding failure due to the stress thereof. Thus, the bonding reliability between the substrate and the electronic component and the reliability of an electronic device including the substrate and the electronic component may be deteriorated.

Hereinafter, an example of an embodiment of a technology capable of increasing the bonding reliability between a substrate and an electronic component will be described with reference to the drawings. In addition, in the respective drawings, the same or equivalent constituent elements and portions will be denoted by the same reference numerals, and a redundant description thereof will be omitted as appropriate.

First, a technology to bond an electronic component and a substrate to each other will be described. A surface mount type electronic component such as a land grid array (LGA) or a quad flat no lead package (QFN) is mounted on a substrate such as, for example, a printed circuit substrate using a bonding material such as, for example, a solder. In this case, there may be a case where the bonding reliability between the electronic component and the substrate, for example, the bonding durability due to a heat cycle or external stress may not be sufficiently satisfied.

As a measure of such a case, a method of securing (increasing) the height of a bonding element, thereby prolonging the lifespan of the bonding element has been known. For example, in a process of printing a solder paste on a substrate, a method of enlarging the size of an opening in a metal mask or increasing the thickness of the metal mask, thereby increasing the amount of a solder to be supplied onto the substrate so as to increase the height of a bonding element has been known. However, in the method of increasing the amount of the solder to be supplied as described above, the height of the bonding element may be increased only by about several micrometers and the effect of sufficiently prolonging the lifetime of the bonding element may not be obtained occasionally.

As another measure, a method called “underfill” or “sidefill” in which an electronic component and a substrate are bonded and fixed to each other with a bonding material such as, for example, a resin has also been known. Underfill is a method of introducing a filler-containing resin between the electronic component and the substrate to fix the electronic component and the substrate to each other, and has a relatively high effect of prolonging the lifespan of a bonding element. However, in a case of an electronic component in the form of an LGA or a QFN, since the interval between the substrate and the electronic component is narrow and the height of the bonding element is low (about 40 μm), it is not always easy to fill the filler-containing resin between the substrate and the electronic component. On the other hand, sidefill is a method of fixing the outer periphery or corner of an electronic component with a resin, but the lifespan of a bonding element may be shortened by fixing the outer periphery or corner of the electronic component as described above.

In addition, there is a case where a substrate on which an electronic component is mounted is fastened to another component such as, for example, a housing of an electronic apparatus with a screw when the substrate is mounted on the electronic apparatus. In such a case, since the substrate is fastened with the screw, a force acts on the mounting area for the electronic component from a screw fastening portion of the substrate. Therefore, stress (or distortion) may occur in a bonding element between the electronic component and the substrate, and the lifespan of the bonding element may be shortened due to, for example, cracks or fractures caused by the stress.

Hereinafter, an example of an embodiment of a technology capable of increasing the bonding reliability between a substrate and an electronic component will be described with reference to the drawings. In addition, in the respective drawings, the same or equivalent constituent elements and portions will be denoted by the same reference numerals, and a redundant description thereof will be omitted as appropriate.

First Embodiment

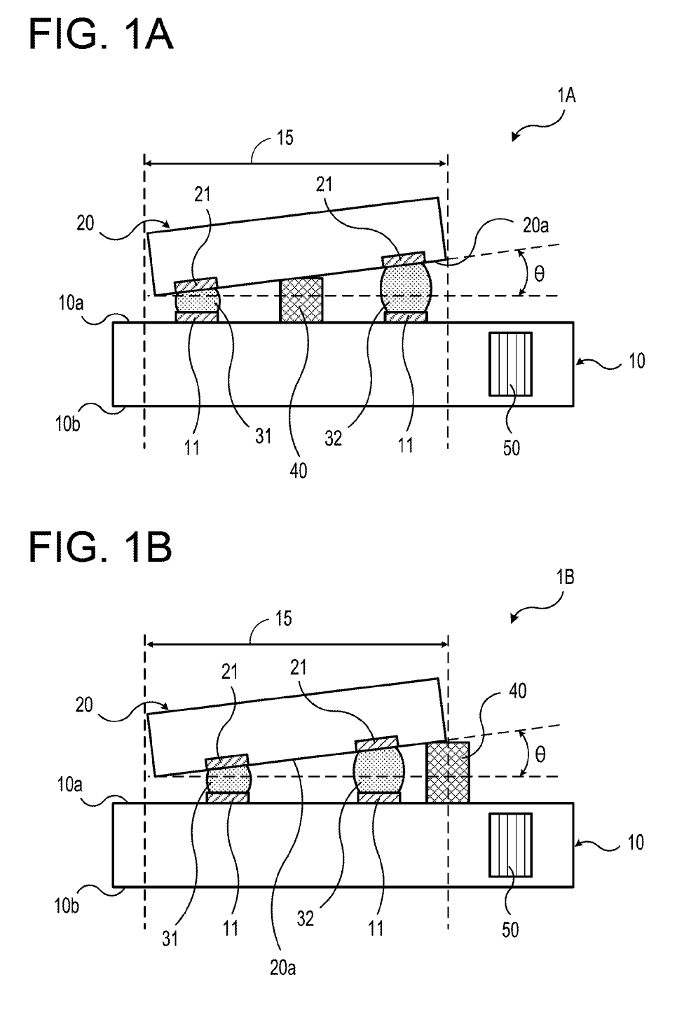

FIGS. 1A and 1B are views illustrating examples of an electronic device according to a first embodiment. FIGS. 1A and 1B schematically illustrate cross-sectional views of major parts of the example of the electronic device, respectively.

First, the electronic device 1A illustrated in FIG. 1A will be described. The electronic device 1A illustrated in FIG. 1A includes a substrate 10, an electronic component 20, a bonding element 31, a bonding element 32, a spacer 40, and a stress generation source 50.

For example, various circuit boards such as, for example, a printed circuit board, a package board, an interposer, a mother board, and a daughter board are used for the substrate 10. Terminals 11 are provided on one surface (upper surface) 10a of the substrate 10 for electrically interconnecting the substrate 10 and another electronic component. Any of various conductor materials, for example, a metal material such as, for example, copper (Cu) is used for the terminals 11. A conductor pattern such as, for example, a wiring or via (not illustrated) which is electrically connected to the terminals 11 on the upper surface 10a is provided within the substrate 10. A conductor pattern such as, for example, a wiring (not illustrated) which is electrically connected to the conductor pattern within the substrate 10 may be provided on the other surface (lower surface) 10b of the substrate 10. In addition to a circuit board, for example, a semiconductor chip or a semiconductor package on which a semiconductor chip is mounted may be used for the substrate 10.

For example, a semiconductor device such as, for example, a surface mount type semiconductor chip or semiconductor package is used for the electronic component 20. Terminals 21 are provided on one surface (lower surface) 20a of the electronic component 20 for electrically interconnecting the electronic component 20 and another electronic component, i.e., the substrate 10 in this example. Any of various conductor materials, for example, a metal material such as, for example, Cu is used for the terminals 21. A conductor pattern such as, for example, a wiring or via (not illustrated) which is electrically connected to the terminals 21 on the lower surface 20a and a circuit element such as, for example, a transistor are provided within the electronic component 20. The terminals 21 of the electronic component 20 are provided at positions corresponding to the respective terminals 11 of the substrate 10. The electronic component 20 is disposed such that the lower surface 20a thereof faces the upper surface 10a of the substrate 10, and is mounted on the substrate 10. In addition to the semiconductor device, a chip component such as, for example, a resistor, a capacitor, or an inductor or a circuit board such as, for example, a printed circuit board may be used for the electronic component 20.

A bonding material such as, for example, a solder is used for the bonding element 31 and the bonding element 32. The bonding element 31 and the bonding element 32 are provided between the substrate 10 and the electronic component 20 which are disposed so as to face each other, and electrically and mechanically interconnect the substrate 10 and the electronic component 20. The bonding element 31 and the bonding element 32 are respectively interposed between the terminals 11 of the substrate 10 and the terminals 21 of the electronic component 20 which are provided at different positions so as to correspond to each other, and bond the terminals 11 of the substrate 10 and the terminals 21 of the electronic component 20 to each other at different positions. The electronic device 1A is formed such that the height of one bonding element 31 is lower than the height of the other bonding element 32.

The spacer 40 is provided between the substrate 10 and the electronic component 20 which are arranged so as to face each other. In the electronic device 1A, the spacer 40 is provided inside the bonding element 31 and the bonding element 32 which bond the substrate 10 and the electronic component 20 to each other. Although one spacer 40 is illustrated in FIG. 1A as an example, a plurality of spacers 40 may be provided between the substrate 10 and the electronic component 20 inside the bonding element 31 and the bonding element 32. The spacer 40 is provided at a predetermined position between the substrate 10 and the electronic component 20 to have a predetermined height. Any of various materials is used for the spacer 40. For example, a material such as an insulating material such as, for example, a resin, glass, or ceramic, a conductor material such as, for example, a metal, or a semiconductor material such as, for example, silicon (Si) is used for a part or the whole of the spacer 40. One or more kinds of such materials are used for the spacer 40.

In the electronic device 1A, the electronic component 20 which is mounted on the substrate 10 with the spacer 40 interposed therebetween is bonded to the substrate 10 at the bonding element 31 and the bonding element 32 in a state where the area inside the bonding element 31 and the bonding element 32 is supported by the spacer 40. Since the spacer 40 is provided inside the bonding element 31 and the bonding element 32 and since the height of the bonding element 32 is higher than the height of the bonding element 31, the electronic element 20 is mounted on the substrate 10 so as to be inclined by an angle θ with respect to the upper surface 10a of the substrate 10. For example, the height and position of the spacer 40 and the respective heights of the bonding element 31 and the bonding element 32 are set so that the inclination angle θ is about 2° to 5°.

The stress generation source 50 is provided in the substrate 10 and generates stress in an area (mounting area) 15 of the substrate 10 on which the electronic component 20 is mounted. For example, the stress generation source 50 is a screw fastening portion when the substrate 10 is fastened to a component such as another electronic component or a housing with a screw. Alternatively, the stress generation source 50 may be, for example, a conductor via which is formed by filling the inside of the substrate 10 with a metal material such as, for example, Cu.

In the electronic device 1A, since the spacer 40 is provided between the substrate 10 and the electronic component 20, a gap of a certain value or higher is secured between the substrate 10 and the electronic component 20 and a height of a certain value or higher of a certain value or higher is secured for both the bonding element 31 and the bonding element 32. By securing the height of a certain value or higher for the bonding element 31 and the bonding element 32, the effect of alleviating the stress generated in the bonding element 31 and the bonding element 32 is enhanced and the lifespan of both the bonding element 31 and the bonding element 32 is prolonged.

In addition, in the electronic device 1A, the bonding element 32 which is close to the stress generation source 50 is formed so as to have a height higher than that of the bonding element 31 which is far from the stress generation source 50. In the bonding element 32 having a high height, the effect of alleviating the stress (or distortion) generated against external stress is greater than that in the bonding element 31 having a low height. Since the height of the bonding element 32 which is close to the stress generation source 50 and generates relatively large stress is higher than the height of the bonding element 32 which is far from the stress generation source 50 and generates relatively small stress, the lifespan of both the bonding element 31 and the bonding element 32 is prolonged.

For example, when bonding elements between the substrate 10 and the electronic component 20 have a constant height regardless of a difference in the distance from the stress generation source 50, the lifespan of the bonding element which is close to the stress generation source 50 may be shortened. On the other hand, in the electronic device 1A, since a height of a certain value or higher is secured for both the bonding element 31 and the bonding element 32 by the spacer 40 and since the bonding element 32 which is closer to the stress generation source 50 is formed so as to be higher, the lifespan of both the bonding element 31 and the bonding element 32 is prolonged. Therefore, the electronic device 1A having high bonding reliability between the substrate 10 and the electronic component 20 is realized.

Subsequently, the electronic device 1B illustrated in FIG. 1B will be described. The electronic device 1B illustrated in FIG. 1B differs from the electronic device 1A illustrated in FIG. 1A in that the spacer 40 between the substrate 10 and the electronic component 20 is provided outside the bonding element 31 and the bonding element 32 which bond the substrate 10 and the electronic component 20 to each other. Although one spacer 40 is illustrated in FIG. 1B as an example, a plurality of spacers 40 may be provided between the substrate 10 and the electronic component 20 outside the bonding element 31 and the bonding element 32.

In the electronic device 1B, in a state where the area of the electronic component 20 outside the bonding element 31 and the bonding element 32 is supported by the spacer 40, the electronic component 20 which is mounted on the substrate 10 with the spacer 40 interposed therebetween is bonded to the substrate 10 at the bonding element 31 and the bonding element 32. Since the spacer 40 is provided outside the bonding element 31 and the bonding element 32 and since the height of the bonding element 32 is higher than the height of the bonding element 31, the electronic component 20 is mounted on the substrate 10 so as to be inclined by an angle θ with respect to the upper surface 10a of the substrate 10. For example, the height and position of the spacer 40 and the respective heights of the bonding element 31 and the bonding element 32 are set so that the angle θ is about 2° to 5°.

In the electronic device 1B, since the spacer 40 is provided between the substrate 10 and the electronic component 20 and since a height of a certain value or higher is secured for the bonding element 31 and the bonding element 32, the effect of alleviating the stress generated in the bonding element 31 and the bonding element 32 is enhanced and the lifespan of the bonding element 31 and the bonding element 32 is prolonged. In addition, in the electronic device 1B, since the height of the bonding element 32 which is close to the stress generation source 50 and generates relatively large stress is higher than the height of the bonding element 31 which is far from the stress generation source 50 and generates relatively small stress, the lifespan of the bonding element 31 and the bonding element 32 is prolonged. Therefore, the electronic device 1B having high bonding reliability between the substrate 10 and the electronic component 20 is realized.

Second Embodiment

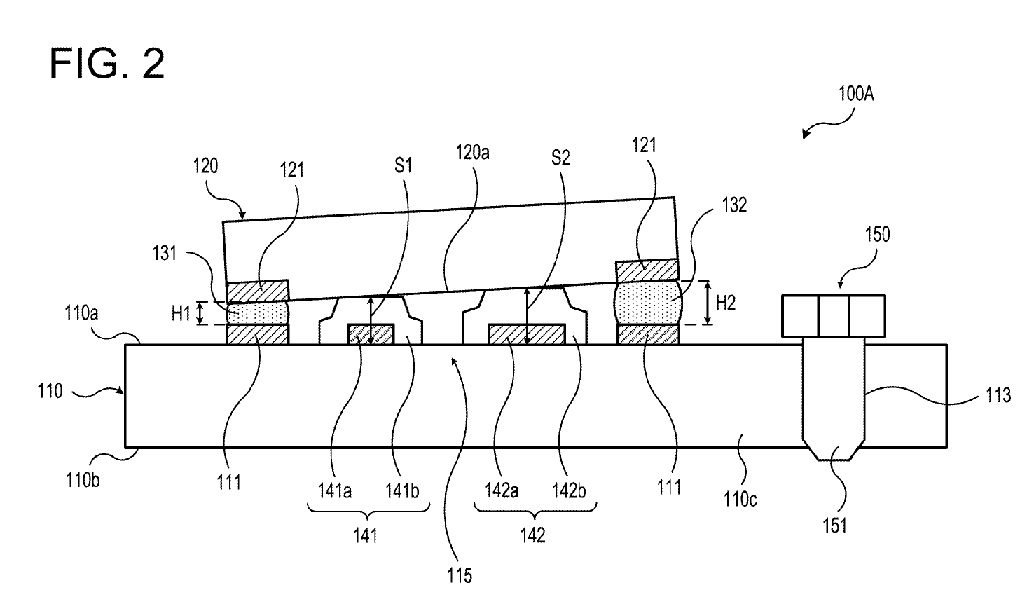

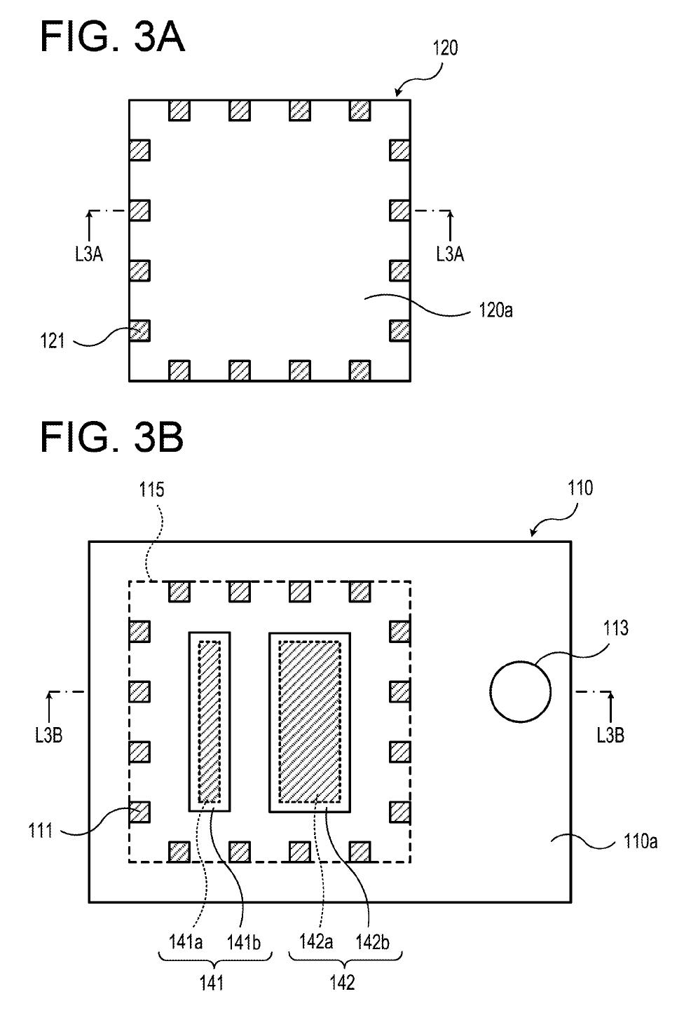

FIGS. 2, 3A and 3B are views illustrating a first example of an electronic device according to a second embodiment. FIG. 2 schematically illustrates a cross-sectional view of major parts of an example of the electronic device. FIG. 3A schematically illustrates a plan view of major parts of the semiconductor device viewed from the terminal surface side, and FIG. 3B schematically illustrates a plan view of major parts of the printed circuit board viewed from the terminal surface side. In addition, FIG. 2 is a view corresponding to the position of the L3A-L3A cross section of FIG. 3A and the position of the L3B-L3B cross section of FIG. 3B.

The electronic device 100A illustrated in FIG. 2 includes a printed circuit board 110, a semiconductor device 120, a solder bonding element 131, a solder bonding element 132, a pedestal 141, a pedestal 142, and a screw fastening portion 150. Here, the printed circuit board 110 is an example of the substrate 10 described in the first embodiment. The semiconductor device 120 is an example of the electronic component 20 described in the first embodiment. The solder bonding element 131 and the solder bonding element 132 are examples of the bonding element 31 and the bonding element 32 described in the first embodiment. The pedestal 141 and the pedestal 142 are examples of the spacer 40 described in the first embodiment. The screw fastening portion 150 is an example of the stress generation source 50 described in the first embodiment.

As illustrated in FIGS. 2 and 3B, the printed circuit board 110 includes terminals 111 provided on one surface 110a thereof (upper surface of a board 110c) which faces the semiconductor device 120 to be mounted. Any of various conductor materials such as, for example, Cu is used for the terminals 111. A conductor pattern such as, for example, a wiring or via (not illustrated) which is electrically connected to the terminals 111 on the upper surface 110a is provided within the printed circuit board 110. A conductor pattern such as, for example, a wiring (not illustrated) which is electrically connected to the conductor pattern within the printed circuit board 110 may be provided on the other surface 110b of the printed circuit board 110 (lower surface of the board 110c).

The semiconductor device 120 is a surface mount type semiconductor device, and for example, is a QFN type semiconductor device. As illustrated in FIGS. 2 and 3A, the semiconductor device 120 includes terminals 121 provided on one surface (lower surface) 120a thereof which faces the printed circuit board 110 on which the semiconductor device 120 is to be mounted. In a case of the QFN, the terminals 121 are arranged along the edge of the lower surface 120a of the semiconductor device 120. The terminals 121 of the semiconductor device 120 are provided at positions corresponding to the terminals 111 of the printed circuit board 110. Any of various conductor materials such as, for example, Cu is used for the terminals 121. A conductor pattern such as, for example, a wiring or via (not illustrated) which is electrically connected to the terminals 121 on the lower surface 120a and a circuit element such as, for example, a transistor are provided within the semiconductor device 120. The semiconductor device 120 is disposed such that the lower surface 120a thereof faces the upper surface 110a of the printed circuit board 110 and is mounted on the printed circuit board 110.

The solder bonding element 131 and the solder bonding element 132 are bonding elements that are formed using a solder as a bonding material. As illustrated in FIG. 2, the solder bonding element 131 and the solder bonding element 132 are provided between the printed circuit board 110 and the semiconductor device 120 which are disposed so as to face each other, and electrically and mechanically interconnect the printed circuit board 110 and the semiconductor device 120. The solder bonding element 131 and the solder bonding element 132 respectively bond the terminals 111 of the printed circuit board 110 and the terminals 121 of the semiconductor device 120 which are provided at different positions so as to correspond to each other. As illustrated in FIG. 2, the solder bonding element 131 which is relatively far from the screw fastening portion 150 is formed to have a height H1, and the solder bonding element 132 which is relatively close to the screw fastening portion 150 is formed to have a height H2 (>H1) higher than the solder bonding element 131.

As illustrated in FIGS. 2 and 3B, the pedestal 141 and the pedestal 142 are provided in an area (mounting area) 115 of the upper surface 110a of the printed circuit board 110 in which the semiconductor device 120 is mounted. The pedestal 141 and the pedestal 142 are provided inside the terminals 111 of the printed circuit board 110, in other words, inside the solder bonding element 131 and the solder bonding element 132 formed between the printed circuit board 110 and the semiconductor device 120. Although two pedestals 141 and 142 illustrated in FIGS. 2 and 3B as an example, one pedestal or three or more pedestals may be provided inside the terminals 111 of the printed circuit board 110. The pedestal 141 and the pedestal 142 are provided at predetermined positions between the printed circuit board 110 and the semiconductor device 120 to have predetermined heights, respectively.

As illustrated in FIGS. 2 and 3B, one pedestal 141 includes a conductor layer 141a provided on the upper surface 110a of the printed circuit board 110 and an insulating layer 141b provided on the conductor layer 141a so as to cover the conductor layer 141a. As illustrated in FIGS. 2 and 3B, the other pedestal 142 includes a conductor layer 142a provided on the upper surface 110a of the printed circuit board 110 and an insulating layer 142b provided so as to cover the conductor layer 142a. For example, the same material as the terminals 111 provided on the upper surface 110a is used for the conductor layer 141a and the conductor layer 142a. Any of various insulating materials, for example, a resin material such as, for example, a solder resist is used for the insulating layer 141b and the insulating layer 142b.

For example, the conductor layer 141a and the conductor layer 142a are provided to have different widths, and the conductor layer 142a which is relatively close to the screw fastening portion 150 is formed so as to be wider than the conductor layer 141a which is relatively far from the screw fastening portion 150 in the cross sectional view and the plan view. When, for example, a solder resist is applied as the insulating layer 141b and the insulating layer 142b onto the conductor layer 141a and the conductor layer 142a having different widths, the insulating layer 142b which covers the wider conductor layer 142a is thicker than the insulating layer 141b which covers the narrower conductor layer 141a. As a result, as illustrated in FIG. 2, when the pedestal 141 which is relatively far from the screw fastening portion 150 is formed to have a height S1, the pedestal 142 which is relatively close to the screw fastening portion 150 is formed to have a height S2 (>S1) higher than the pedestal 141. In addition, details of the formation of the pedestal 141 and the pedestal 142 having different heights will further be described later (fifth embodiment).

In the electronic device 100A, as illustrated in FIG. 2, in a state where the area of the semiconductor device 120 inside the solder bonding element 131 and the solder bonding element 132 is supported by the pedestal 141 and the pedestal 142, the semiconductor device 120 is bonded to the printed circuit board 110 at the solder bonding element 131 and the solder bonding element 132. Since the pedestal 141 and the pedestal 142 higher than the pedestal 141 are provided inside the solder bonding element 131 and the solder bonding element 132 and since the solder bonding element 132 is higher than the solder bonding element 131, the semiconductor device 120 is mounted so as to be inclined with respect to the printed circuit board 110. For example, the heights and positions of the pedestal 141 and the pedestal 142 and the respective heights of the solder bonding element 131 and the solder bonding element 132 are set so that the inclination angle θ is about 2° to 5°.

When fastening the printed circuit board 110 to another component such as, for example, a housing with a screw, the screw fastening portion 150 is a portion in which a screw 151 is inserted through a hole 113 formed in the printed circuit board 110 and the printed circuit board 110 is fastened (fixedly screwed) to the housing, for example, with the screw 115. When such a screw fastening portion 150 is present, a force acts on the printed circuit board 110 from the screw fastening portion 150 to the mounting area 115 of the semiconductor device 120. Thus, the stress (or distortion) occurs in the bonding element between the semiconductor device 120 and the printed circuit board 110. This stress increases with a decreasing distance to the screw fastening portion 150 and decreases with an increasing distance from the screw fastening portion 150. In addition, the screw fastening portion 150 in which the screw 151 is inserted through the hole 113 to fasten the printed circuit board 110 to a housing, for example, may be a source which generates stress, and the hole 113 in the printed circuit board 110 before the screw 151 is inserted through the hole 113 may also be a source which generates stress.

In the electronic device 100A, since the pedestal 141 and the pedestal 142 are provided between the printed circuit board 110 and the semiconductor device 120, a gap of a certain value or higher is secured between the printed circuit board 110 and the semiconductor device 120. By performing bonding using a solder in a state where the gap is secured in this manner, a height of a certain value or higher is secured for the solder bonding element 131 and the solder bonding element 132. By securing a height of a certain value or higher for the solder bonding element 131 and the solder bonding element 132, the effect of alleviating the stress generated in the solder bonding element 131 and the solder bonding element 132 is enhanced and the lifespan of both the solder bonding element 131 and the solder bonding element 132 is prolonged.

In addition, in the electronic device 100A, the height of the solder bonding element 132 which is close to the screw fastening portion 150 which is a stress generation source is higher than the height of the solder bonding element 131 which is far from the screw fastening portion 150. In the solder bonding element 132 having a high height, the effect of alleviating the stress generated against external stress is greater than that in the solder bonding element 131 having a low height. Since the height of the solder bonding element 132 which is close to the screw fastening portion 150 and generates relatively large stress is higher than the height of the solder bonding element 131 which is far from the screw fastening portion 150 and generates relatively small stress, the lifespan of both the solder bonding element 131 and the solder bonding element 132 is prolonged. According to the above configuration, the electronic device 100A having high bonding reliability between the printed circuit board 110 and the semiconductor device 120 is realized.

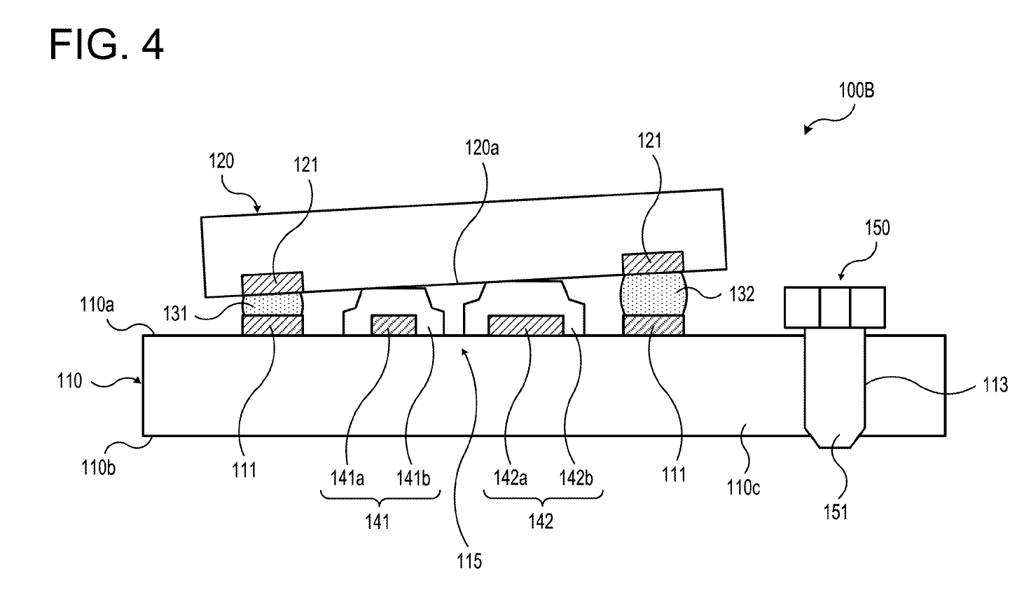

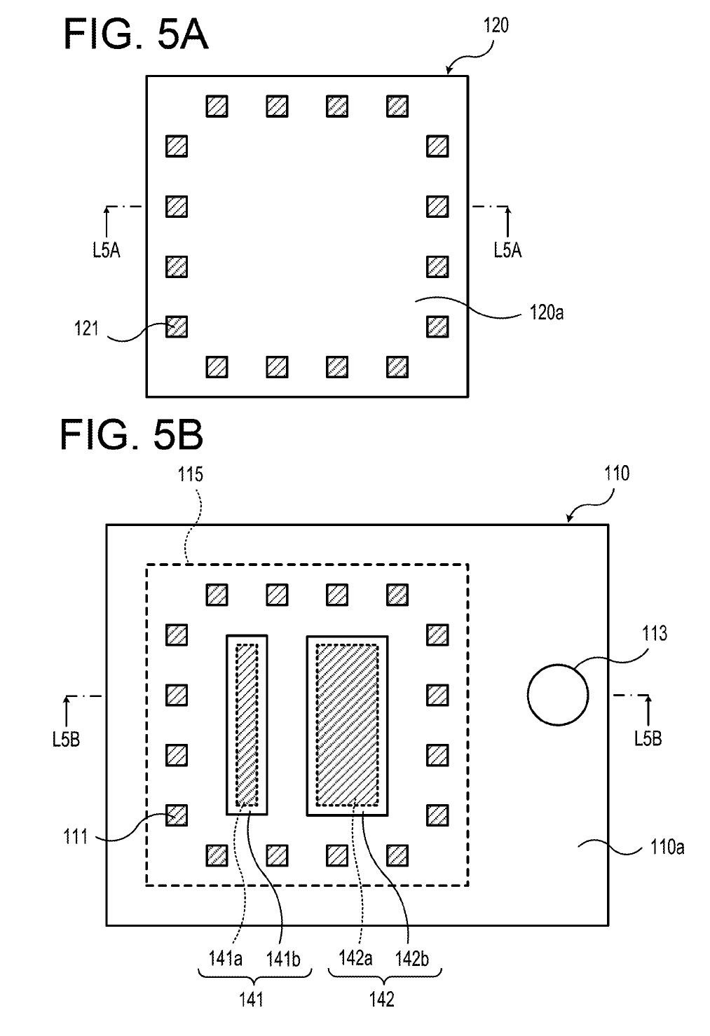

FIGS. 4, 5A and 5B are views illustrating a second example of the electronic device according to the second embodiment. FIG. 4 schematically illustrates a cross-sectional view of major parts of an example of the electronic device. FIG. 5A schematically illustrates a plan view of major parts of the semiconductor device viewed from the terminal surface side, and FIG. 5B schematically illustrates a plan view of major parts of the printed circuit board viewed from the terminal surface side. In addition, FIG. 4 is a view corresponding to the position of the L5A-L5A cross section of FIG. 5A and the position of the L5B-L5B cross section of FIG. 5B.

In the electronic device 100B illustrated in FIG. 4, as the semiconductor device 120, as illustrated in FIGS. 4 and 5A, an LGA type semiconductor device is used in which the terminals 121 are arranged along the edge of the lower surface 120a which faces the printed circuit board 110 at positions inside the edge. In this respect, the electronic device 100B differs from the electronic device 100A.

Similarly to a case where the semiconductor device 120 as illustrated in FIGS. 4 and 5A is mounted, the solder bonding element 131 and the solder bonding element 132 as illustrated in FIG. 4 and the pedestal 141 and the pedestal 142 as illustrated in FIGS. 4 and 5B are provided in the mounting area 115 of the printed circuit board 110.

That is, the solder bonding element 131 and the solder bonding element 132 are provided such that the height of the solder bonding element 132 formed between the terminals 111 and 121 which is relatively close to the screw fastening portion 150 is higher than the height of the solder bonding element 131 formed between the terminals 111 and 121 which is relatively far from the screw fastening portion 150. The pedestal 141 and the pedestal 142 are provided inside the solder bonding element 131 and the solder bonding element 132 such that the height of the pedestal 142 which is relatively close to the screw fastening portion 150 is higher than the height of the pedestal 141 which is relatively far from the screw fastening portion 150.

Even in such an electronic device 100B, similarly to the electronic device 100A, the pedestal 141 and the pedestal 142 are provided between the printed circuit board 110 and the semiconductor device 120, and a height of a certain value or higher is secured for the solder bonding element 131 and the solder bonding element 132. Therefore, the effect of alleviating the stress generated in the solder bonding element 131 and the solder bonding element 132 is enhanced, and the lifespan of both the solder bonding element 131 and the solder bonding element 132 is prolonged.

In addition, in the electronic device 100B, the height of the solder bonding element 132 which is close to the screw fastening portion 150 and generates relatively large stress is higher than the height of the solder bonding element 131 which is far from the screw fastening portion 150 and generates relatively small stress. Therefore, the lifespan of both the solder bonding element 131 and the solder bonding element 132 is prolonged.

According to the above configuration, the electronic device 100B having high bonding reliability between the printed circuit board 110 and the semiconductor device 120 is realized.

Third Embodiment

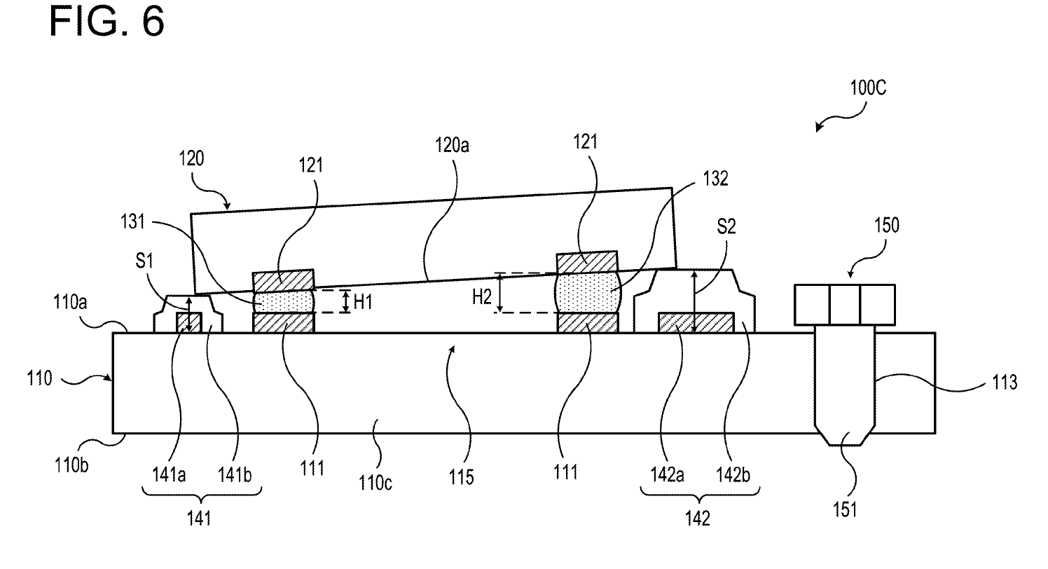

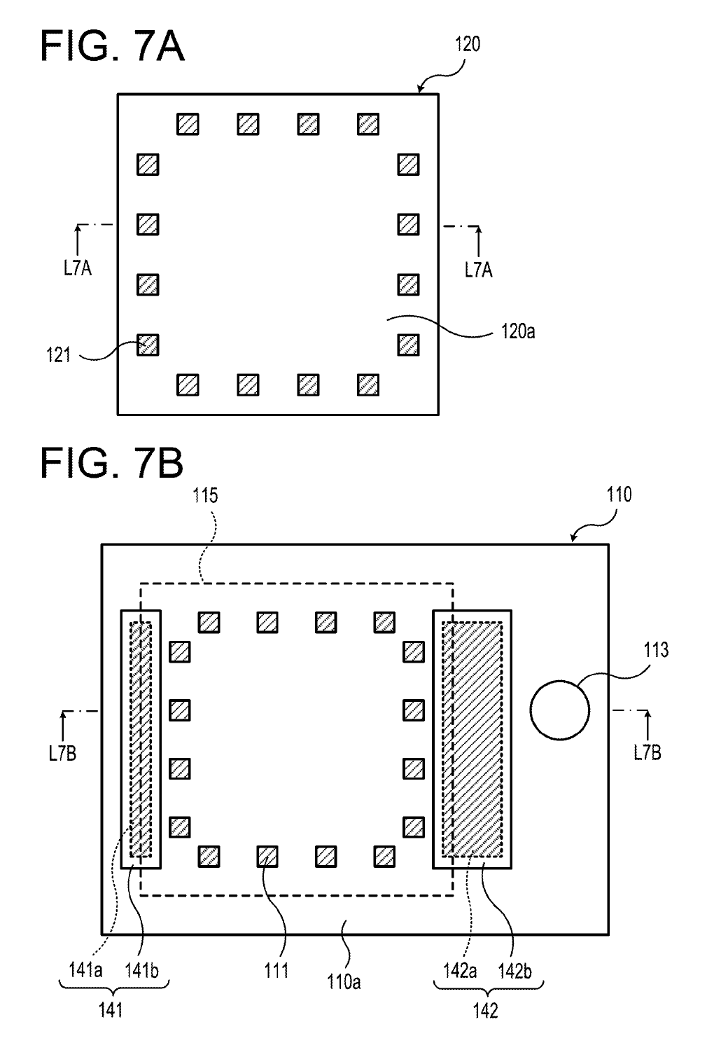

FIGS. 6, 7A and 7B are views illustrating a first example of an electronic device according to a third embodiment. FIG. 6 schematically illustrates a cross-sectional view of major parts of an example of the electronic device. FIG. 7A schematically illustrates a plan view of major parts of the semiconductor device viewed from the terminal surface side, and FIG. 7B schematically illustrates a plan view of major parts of the printed circuit board viewed from the terminal surface side. In addition, FIG. 6 is a view corresponding to the position of the L7A-L7A cross section of FIG. 7A and the position of the L7B-L7B cross section of FIG. 7B.

In the electronic device 100C illustrated in FIG. 6, as the semiconductor device 120, as illustrated in FIGS. 6 and 7A, an LGA type semiconductor device is used in which the terminals 121 are arranged along the edge of the lower surface 120a which faces the printed circuit board 110 at positions inside the edge. In the electronic device 100C, the semiconductor device 120 is bonded to the printed circuit board 110 using the solder bonding element 131 and the solder bonding element 132, and the pedestal 141 and the pedestal 142 are provided outside the solder bonding element 131 and the solder bonding element 132.

As illustrated in FIG. 6, the solder bonding element 131 which is relatively far from the screw fastening portion 150 is formed to have a height H1, and the solder bonding element 132 which is relatively close to the screw fastening portion 150 is formed to have a height H2 (>H1) higher than the solder bonding element 131.

As illustrated in FIGS. 6 and FIG. 7B, a portion of each of the pedestal 141 and the pedestal 142 is provided in the mounting area 115 of the printed circuit board 110, and a remaining portion thereof is provided outside the terminals 111 of the printed circuit board 110, in other words, outside the solder bonding element 131 and the solder bonding element 132. As illustrated in FIG. 6, the pedestal 141 which is relatively far from the screw fastening portion 150 is formed to have a height S1, and the pedestal 142 which is relatively close to the screw fastening portion 150 is formed to have a height S2 (>S1) higher than the pedestal 141.

In the electronic device 100C, as illustrated in FIG. 6, in a state where the area of the semiconductor device 120 outside the solder bonding element 131 and the solder bonding element 132 is supported by the pedestal 141 and the pedestal 142, the semiconductor device 120 is bonded to the printed circuit board 110 at the solder bonding element 131 and the solder bonding element 132. Since the pedestal 141 and the pedestal 142 higher than the pedestal 141 are provided outside the solder bonding element 131 and the solder bonding element 132 and since the solder bonding element 132 is formed so as to be higher than the solder bonding element 131, the semiconductor device 120 is mounted so as to be inclined with respect to the printed circuit board 110.

Even in such an electronic device 100C, similarly to the description in the second embodiment, the pedestal 141 and the pedestal 142 are provided between the printed circuit board 110 and the semiconductor device 120, and a height of a certain value or higher is secured for the solder bonding element 131 and the solder bonding element 132. Therefore, the effect of alleviating the stress generated in the solder bonding element 131 and the solder bonding element 132 is enhanced, and the lifespan of both the solder bonding element 131 and the solder bonding element 132 is prolonged.

In addition, in the electronic device 100C, since the height of the solder bonding element 132 which is close to the screw fastening portion 150 and generates relatively large stress is higher than the height of the solder bonding element 131 which is far from the screw fastening portion 150 and generates relatively small stress, the lifespan of the solder bonding element 131 and the solder bonding element 132 is prolonged. According to the above configuration, the electronic device 100C having high bonding reliability between the printed circuit board 110 and the semiconductor device 120 is realized.

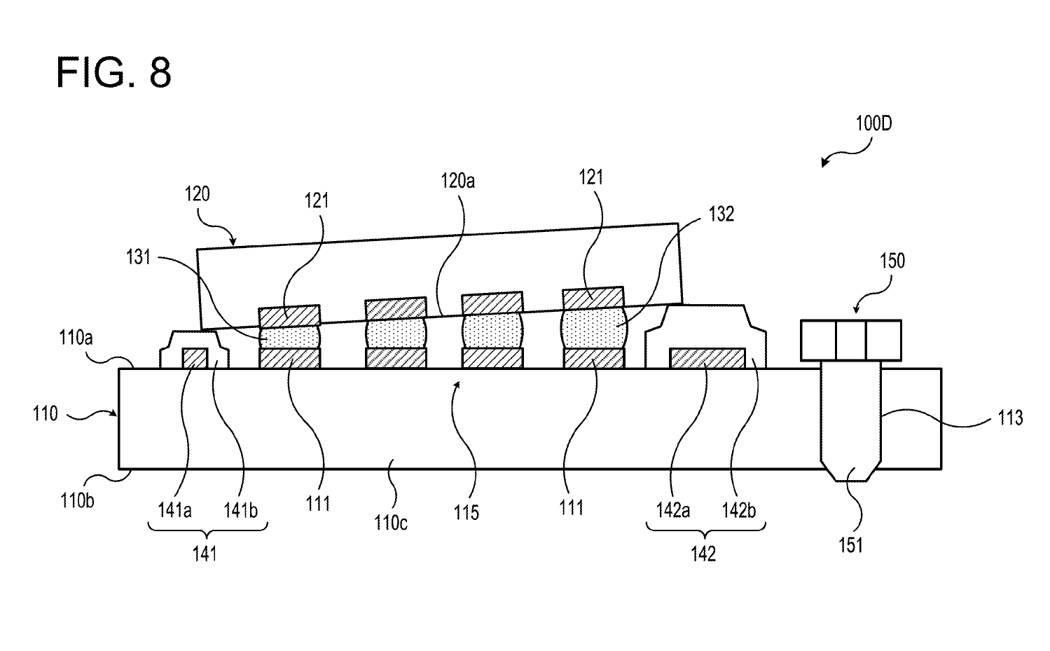

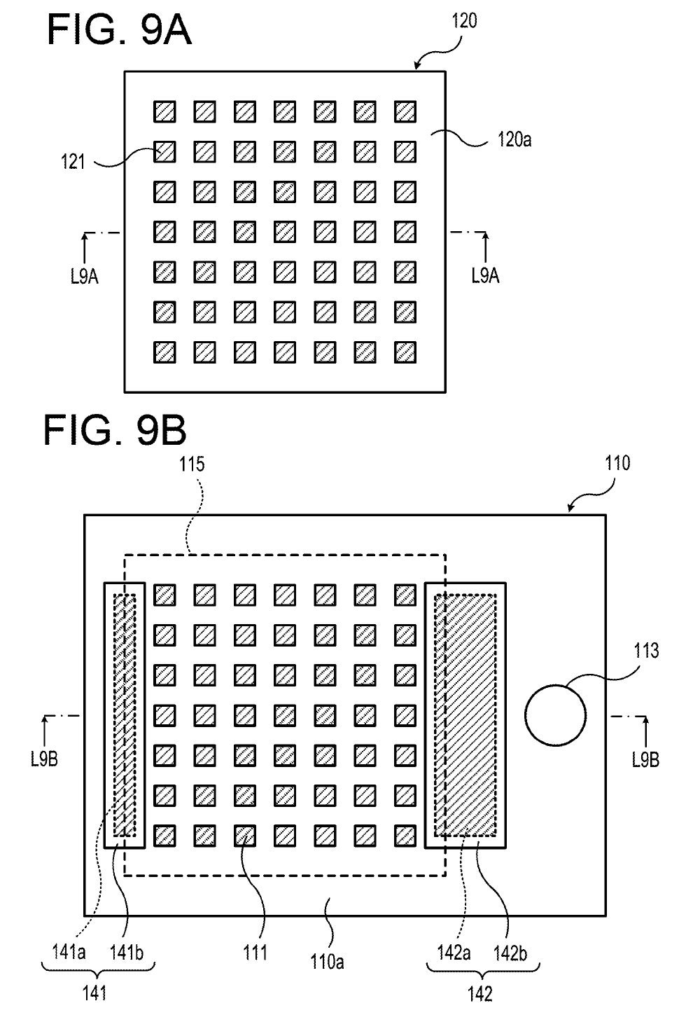

FIGS. 8, 9A and 9B are views illustrating a second example of the electronic device according to the third embodiment. FIG. 8 schematically illustrates a cross-sectional view of major parts of an example of the electronic device. FIG. 9A schematically illustrates a plan view of major parts of the semiconductor device viewed from the terminal surface side, and FIG. 9B schematically illustrates a plan view of major parts of the printed circuit board viewed from the terminal surface side. In addition, FIG. 8 is a view corresponding to the position of the L9A-L9A cross section of FIG. 9A and the position of the L9B-L9B cross section of FIG. 9B.

In the electronic device 100D illustrated in FIG. 8, as the semiconductor device 120, as illustrated in FIGS. 8 and 9A, an LGA type semiconductor device is used in which the terminals 121 are arranged in a matrix form on the lower surface 120a which faces the printed circuit board 110. As illustrated in FIGS. 8 and 9B, in the mounting area 115 of the printed circuit board 110, the terminals 111 are arranged in a matrix form at positions corresponding to the terminals 121 of the LGA type semiconductor device 120. In this respect, the electronic device 100D differs from the electronic device 100C.

Even in a case where the printed circuit board 110 and the semiconductor device 120 in which the terminals 111 and the terminals 121 are provided in a matrix form are bonded to each other, the same effect as described above may be obtained by adopting the pedestal 141 and the pedestal 142, a portion of which is provided in the mounting area 115 of the printed circuit board 110.

That is, the solder bonding element 131 and the solder bonding element 132 are provided such that the solder bonding element 132 formed between the terminals 111 and 121 which is relatively close to the screw fastening portion 150 is higher than the solder bonding element 131 formed between the terminals 111 and 121 which is relatively far from the screw fastening portion 150. The pedestal 141 and the pedestal 142 are provided outside the solder bonding element 131 and the solder bonding element 132 such that the pedestal 141 which is relatively close to the screw fastening portion 150 is higher than the pedestal 141 which is relatively far from the screw fastening portion 150.

Therefore, in the electronic device 100D, similarly to the electronic device 100C, a height of a certain value or higher is secured for the solder bonding element 131 and the solder bonding element 132. Thus, the effect of alleviating the stress in the solder bonding element 131 and the solder bonding element 132 is enhanced and the lifespan thereof is prolonged. In addition, in the electronic device 100D, since the solder bonding element 132 which is close to the screw fastening portion 150 is formed so as to be higher than the solder bonding element 131 which is far from the screw fastening portion 150, the lifespan of both the solder bonding element 131 and the solder bonding element 132 is prolonged.

According to the above configuration, the electronic device 100D having high bonding reliability between the printed circuit board 110 and the semiconductor device 120 is realized.

Fourth Embodiment

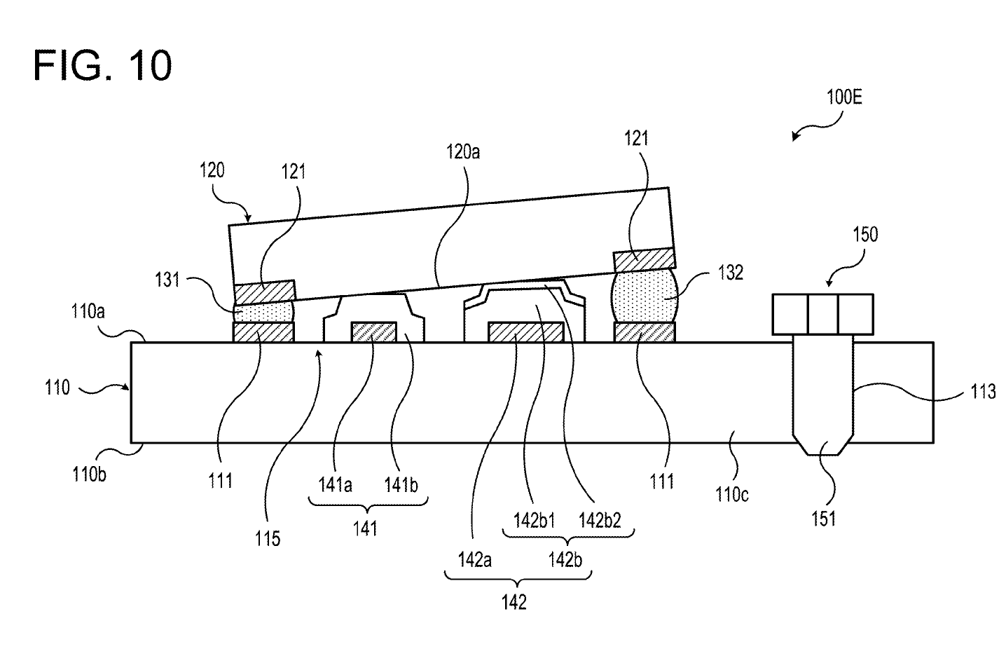

FIG. 10 is a view illustrating an example of an electronic device according to a fourth embodiment. FIG. 10 schematically illustrates a cross-sectional view of major parts of an example of the electronic device.

In the electronic device 100E illustrated in FIG. 10, among the pedestal 141 and the pedestal 142 which are provided inside the solder bonding element 131 and the solder bonding element 132, the insulating layer 142b provided on the conductor layer 142a of one pedestal 142 has a multilayer structure. In this respect, the electronic device 100E differs from the electronic device 100A (FIG. 2) described in the second embodiment.

For example, the insulating layer 142b of the pedestal 142 of the electronic device 100E has a two-layer structure including an insulating layer 142b1 at the lower layer side provided on the conductor layer 142a and an insulating layer 142b2 at the upper layer side provided on the insulating layer 142b1. For example, a solder resist is used for the insulating layer 142b1 at the lower layer side. For example, a silk resin is used for the insulating layer 142b2 at the upper layer side.

In this way, by forming the insulating layer 142b on the conductor layer 142a of the pedestal 142 to have a multilayer structure, for example, a two-layer structure, it is possible to form the pedestal 142 so as to have a higher height, as compared in a case where the conductor layer 142a is covered with the insulating layer 142b1 in a single layer form. For example, in a case where the insulating layer 141b of the lower pedestal 141 and the insulating layer 142b1 of the higher pedestal 142 are formed by a single process of applying a solder resist, the pedestal 141 and the pedestal 142 may not be formed to have a sufficient difference in height by only a difference in width between the conductor layer 141a and the conductor layer 142a. In such a case, since the insulating layer 142b2 is further formed of a silk resin on the insulating layer 142b1 formed of a solder resist, it is possible to form the pedestal 142 having a sufficient difference in height from the pedestal 141 by increasing the height of the pedestal 142.

By increasing the height of the pedestal 142 which is relatively close to the screw fastening portion 150, it is possible to increase the height of the solder bonding element 132 which is relatively close to the screw fastening portion 150. Thus, it is possible to enhance the effect of alleviating the stress in the solder bonding element 132. For example, a case where the solder bonding element 132 is close to the screw fastening portion 150 and the solder bonding element 132 having a height sufficient to alleviate the stress therein may not be realized with the pedestal 142 having the insulation layer 142b1 in a single layer form is conceivable. In such a case, it is effective to increase the height of the pedestal 142 by laminating the insulating layer 142b2 on the insulating layer 142b1 as in the electronic device 100E.

An example in which the insulating layer 142b of the pedestal 142 which is relatively close to the screw fastening portion 150 has a multilayer structure has been described herein, but, similarly, the insulating layer 141b of the pedestal 141 which is relatively far from the screw fastening portion 150 may have a multilayer structure. By forming the insulating layer 141b of the pedestal 141 and the insulating layer 142b of the pedestal 142 to have a multilayer structure, both the solder bonding element 131 and the solder bonding element 132 may be increased in height. Thus, the effect of alleviating the stress in both the solder bonding elements 131 and 132 may be enhanced.

Fifth Embodiment

Here, a method of forming a printed circuit board having a pedestal will be described as a fifth embodiment.

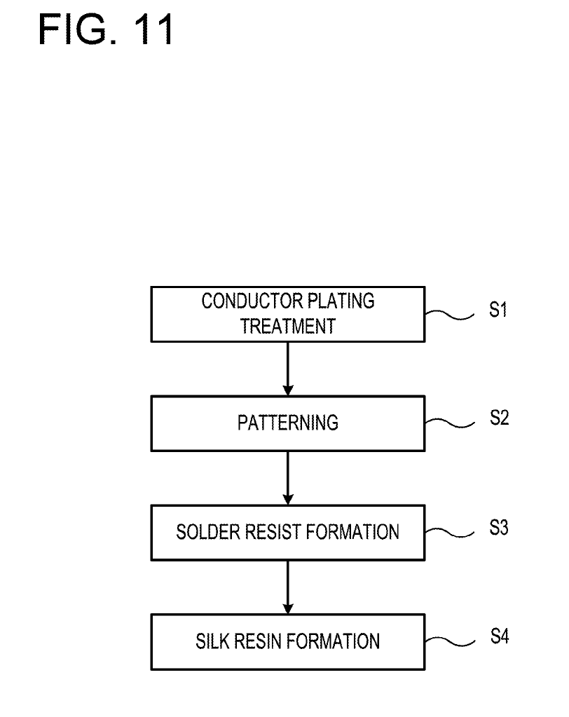

FIG. 11 is a view illustrating an example of a method of forming a pedestal according to a fifth embodiment. In the formation of the printed circuit board 110, first, conductor plating treatment is performed on the board 110c formed with a predetermined conductor pattern (operation S1). The conductor plating treatment is performed by, for example, electrolytic plating treatment or electroless plating treatment using Cu. By the conductor plating treatment in operation S1, a plated layer for forming the terminal 111 is formed. In addition, in the conductor plating treatment in operation S1, a plated layer for forming the conductor layer 141a of the pedestal 141 and a plated layer for forming the conductor layer 142a of the pedestal 142 are formed simultaneously with the formation of the plated layer for forming the terminal 111.

Next, patterning of the plated layer formed on the board 110c is performed (operation S2). The plated layer is patterned by, for example, wet etching. By the patterning of the plated layer in operation S2, the terminal 111 or a wiring including the portion which is to form the terminal 111 is formed at a position corresponding to the terminal 121 of the semiconductor device 120 to be mounted. In addition, in the patterning of the plated layer in operation S2, the conductor layer 141a and the conductor layer 142a having predetermined widths are formed on the board 110c at positions at which the pedestal 141 and the pedestal 142 are to be formed simultaneously with the formation of the terminal 111 or the wiring including the portion which is to form the terminal 111. In the above example, the conductor layer 141a and the conductor layer 142a are formed such that the conductor layer 142a of the pedestal 142 provided at a position which is relatively close to the screw fastening portion 150 is wider than the conductor layer 141a of the pedestal 141 provided at a position which is relatively far from the screw fastening portion 150.

In addition, in the method of simultaneously forming the terminal 111, the conductor layer 141a of the pedestal 141, and the conductor layer 142a of the pedestal 142, the terminal 111, the conductor layer 141a of the pedestal 141, and the conductor layer 142a of the pedestal 142 have the same thickness or substantially the same thickness.

Next, a solder resist is formed on the board 110c (operation S3), and the area excluding the portion which is to form the terminal 111 is covered with the solder resist. The solder resist is formed by applying a predetermined resist material onto the board 110c by, for example, a spin coating method or a spray method. The insulating layer 141b covering the conductor layer 141a and the insulating layer 142b covering the conductor layer 142a are formed of the solder resist formed in operation S3. The insulating layer 141b and the insulating layer 142b are formed on the conductor layer 141a and the conductor layer 142a to have thicknesses (heights) corresponding to the widths of the conductor layer 141a and the conductor layer 142a, respectively.

In a case where a silk resin is not formed on the insulating layer 142b (or on the insulating layer 141b and the insulating layer 142b) in the subsequent process, the pedestal having a low height in which the conductor layer 141a is covered with the insulating layer 141b and the pedestal 142 having a high height in which the conductor layer 142a is covered with the insulating layer 142b are formed by operation S3.

Next, a silk resin is formed on the solder resist formed on the board 110c (operation S4), and predetermined characters, symbols, or figures, for example, are printed on the solder resist. In the formation of the silk resin in operation S4, a silk resin may be formed on the insulating layer 142b formed of the solder resist (or on the insulating layer 141b and the insulating layer 142b). Since the silk resin is formed on the insulating layer 142b (or on the insulating layer 141b and the insulating layer 142b), the pedestal 142 (or the pedestal 141) which is increased in height by the silk resin compared to the height after the formation of the solder resist is formed.

Through the above process, the printed circuit board 110 having the pedestal 141 and the pedestal 142 is formed as described above. In addition, with respect to the pedestal 141 having a low height, the pedestal 141 may be formed using only the insulating layer 141b which is formed of a solder resist without providing the conductor layer 141a.

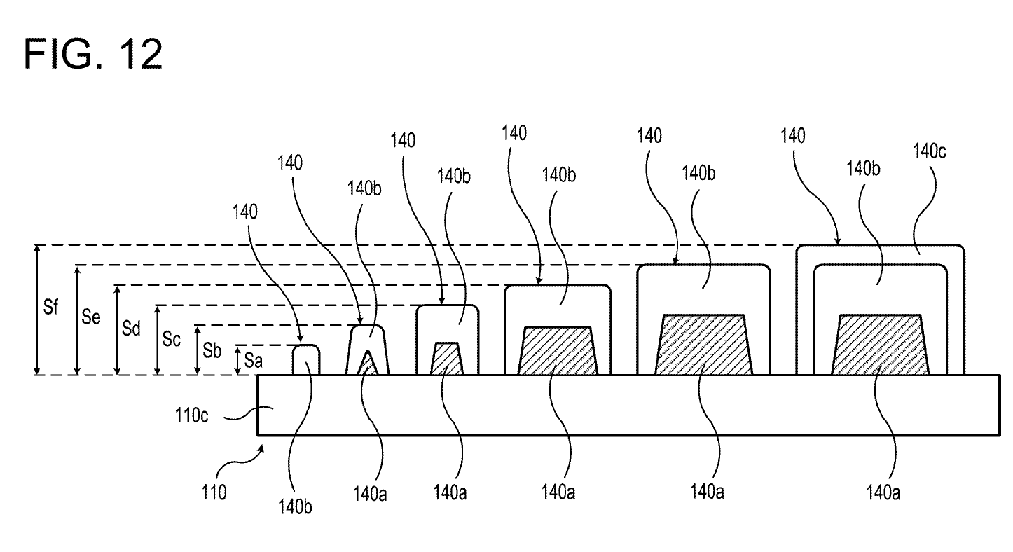

Next, the heights of the pedestal 141 and the base 142 will be described. FIG. 12 is a view for explaining an example of the height adjustment of the pedestal according to the fifth embodiment. FIG. 12 schematically illustrates a cross-sectional view of major parts of various kinds of pedestals which are formed side by side on a printed circuit board.

For example, the height of the pedestal 141 may be adjusted according to the presence or absence of the conductor layer 141a, or the shape such as the width and height of the conductor layer 141a when the conductor layer 141a is provided. For example, the height of the pedestal 142 may be adjusted according to the shape such as the width and height of the conductor layer 142a.

As illustrated in FIG. 12, for example, when an insulating layer 140b (corresponding to the insulating layer 141b or the insulating layer 142b) is formed of a solder resist, for example, on the board 110c having no conductor layer 140a (corresponding to the conductor layer 141a or the conductor layer 142a), a pedestal 140 having a height Sa (the first pedestal 140 from the left in FIG. 12, corresponding to the pedestal 141 or the pedestal 142) is formed.

When the insulating layer 140b is formed of a solder resist, for example, on the board 110c on which the conductor layer 140a having a fine width is formed, the pedestal 140 (the second one from the left in FIG. 12) having a height Sb higher than the height Sa is formed.

When the insulating layer 140b is formed of a solder resist, for example, on the board 110c on which the conductor layer 140a having a width which is larger than the fine width but is relatively small is formed, the pedestal 140 having a height Sc higher than the height Sb (the third one from the left in FIG. 12) is formed.

When the insulating layer 140b is formed of, for example, a solder resist on the board 110c on which the conductor layer 140a having a medium width is formed, the pedestal 140 having a height Sd higher than the height Sc (the fourth one from the left in FIG. 12) is formed.

When the insulating layer 140b is formed of a solder resist, for example, on the board 110c on which the conductor layer 140a having a relatively large width is formed, the pedestal 140 having a height Se higher than the height Sd (the fifth one from the left in FIG. 12) is formed.

When the insulating layer 140b (corresponding to the insulating layer 142b1) is formed of a solder resist, for example, on the board 110c on which the conductor layer 140a having a relatively large width is formed and an insulating layer 140c formed of a silk resin, for example, (corresponding to the insulating layer 142b2) is formed thereon, the pedestal 140 (the sixth one from the left in FIG. 12) having a height Sf higher than the height Se is formed.

In this manner, the height of the pedestal 140 may be adjusted according to the presence or absence of the conductor layer 140a and the shape of the conductor layer 140a.

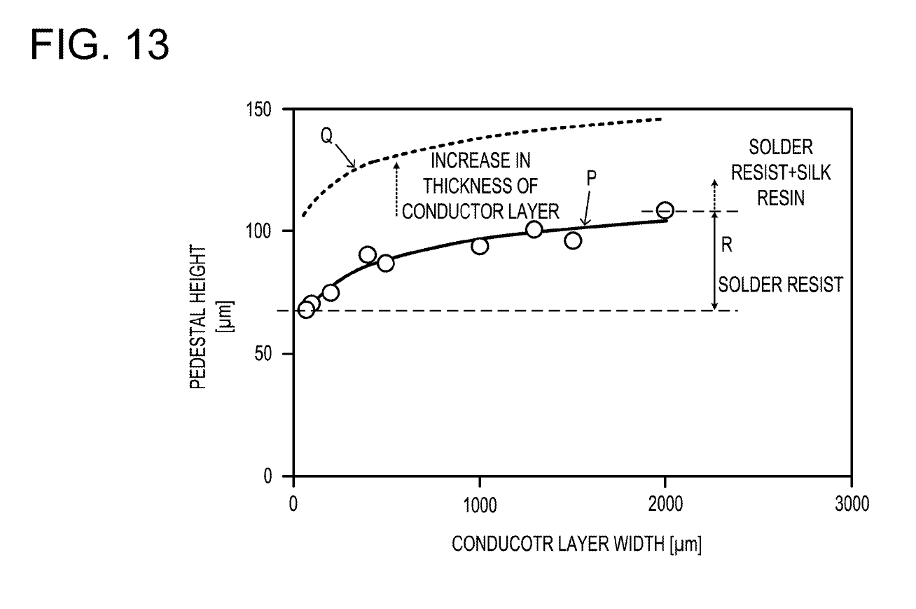

FIG. 13 is a view for explaining a relationship between the width of the conductor layer and the height of the pedestal according to the fifth embodiment. FIG. 13 illustrates an example of a relationship between the width [pm] of the conductor layer 140a and the height [μm] of the pedestal 140 to be formed in a case where the insulating layer 140b is formed using a solder resist on the conductor layer 140a which is formed using Cu (a relationship indicated by plotted points and a solid line P). In this example, the thickness of the conductor layer 140a is set to 70 μm and the length thereof is set to 2000 μm, and the thickness of the insulating layer 140b is set to 25 μm.

It is recognized from FIG. 13 that the height of the pedestal 140 tends to increase with an increase in the width of the conductor layer 140a. The height of the pedestal 140 may be adjusted within a certain range R by adjusting the width of the conductor layer 140a. In a case where the insulating layer 140c is further formed using a silk resin, the range R may further be expanded.

In addition, when the thickness of the conductor layer 140a is increased, the height of the pedestal 140 may further be increased (a relationship indicated by a dotted line Q in FIG. 13).

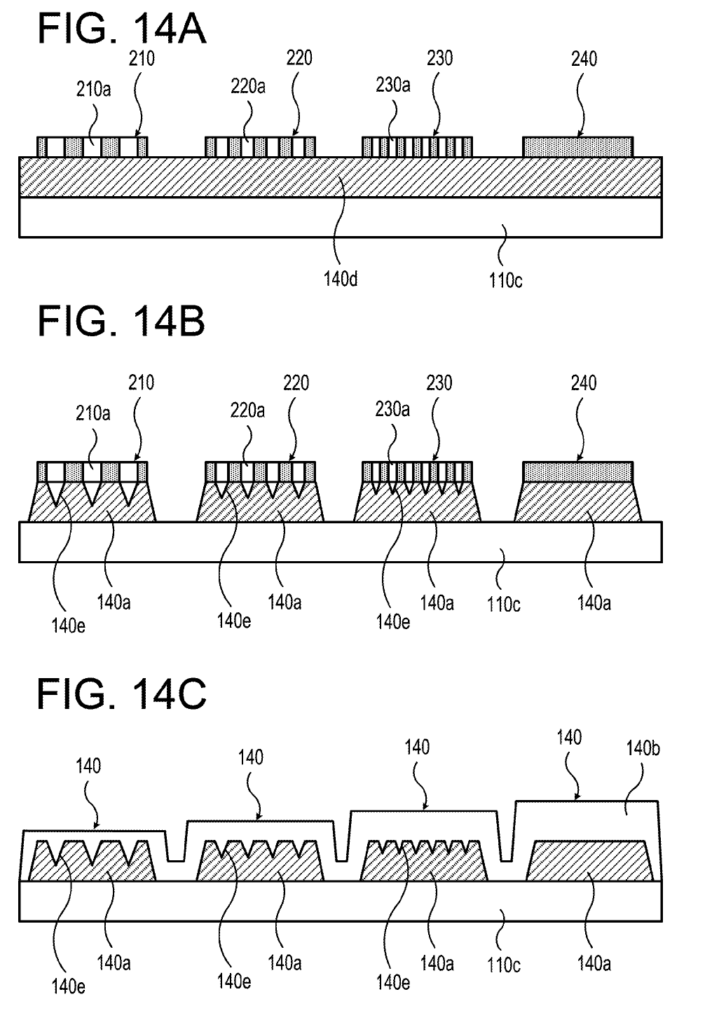

FIGS. 14A to 14C are views for explaining another example of the height adjustment of the pedestal according to the fifth embodiment. FIGS. 14A to 14C schematically illustrate cross-sectional views of major parts of a process of forming various kinds of pedestals formed on a printed circuit board, respectively.

The height of the pedestal 140 (corresponding to the pedestal 141 or the pedestal 142) may be adjusted according to the surface shape of the conductor 140a (corresponding to the conductor layer 141a or the conductor layer 142a), for example, the presence or absence of irregularities on the surface or the size of the irregularities, in addition to the width and height of the conductor layer 140a.

In this case, for example, as illustrated in FIG. 14A, (one or more of) resists 210, 220 and 230 having openings 210a, 220a and 230a are formed on a plated layer 140d formed on the board 110c by conductor plating treatment. In this example, the size of the opening 210a in the resist 210 (the first one from the left) is the largest, and the size is reduced in the order of the opening 220a in the resist 220 (the second one from the left) and the opening 230a in the resist 230 (the third one from the left). The openings 210a, 220a and 230a may have various planar shapes such as a rectangular shape, a circular shape, a linear shape, or a dot shape in a plan view. In addition, a resist 240 (the fourth one from the left) having no opening may be formed on the plated layer 140d.

When the plated layer 140d is half-etched (wet-etched) using the resists 210, 220 and 230 as a mask, the conductor layers 140a which are provided on the surface thereof with irregularities 140e having the sizes corresponding to the openings 210a, 220a and 230a is formed, as illustrated in FIG. 14B. The area and etching rate of the plated layer 140d which are exposed from the openings 210a, 220a and 230a are adjusted according to the sizes of the openings 210a, 220a and 230a, so that the irregularities 140e having the sizes corresponding to the openings 210a, 220a and 230a are formed.

That is, by half-etching using the resist 210 having the largest openings 210a as a mask, the conductor layer 140a (the first one from the left) having the largest irregularities 140e on the surface thereof is formed. According to half-etching using the resists 220 and 230 having the openings 220a and 230a as a mask, the conductor layers 140a (the second and third ones from the left) having the irregularities 140e which are reduced in size in order are formed. In half-etching using the resist 240 having no opening as a mask, formation of irregularities on the surface of the conductor layer 140a (the fourth one from the left) is suppressed.

When the insulating layer 140b is formed of a solder resist, for example, on the board 110c on which the conductor layer 140a is formed, as illustrated in FIG. 14C, the pedestal 140 having a height depending on the presence or absence of irregularities 140e on the surface of the conductor layer 140a and the size of the irregularities 140e when the irregularities 140e are present is formed.

That is, when the insulating layer 140b is formed on the conductor layer 140a having the largest irregularities 140e, an insulating material such as, for example, a solder resist is introduced between the largest irregularities 140e, so that the pedestal 140 having the lowest height (the first one from the left) is formed. In a case where the insulating layer 140b is formed on the conductor layers 140a which are provided on the surface thereof with the irregularities 140e which are sequentially reduced in size, the amount of the insulating material which is introduced between the irregularities 140e which are reduced in size is reduced, so that the pedestals 140 (the second and third ones from the left) which are increased in height in order are formed. In a case where the insulating layer 140b is formed on the conductor layer 140a in which the formation of irregularities on the surface thereof is suppressed, the introduction of the insulating material is suppressed, and the pedestal 140 (the fourth one from the left) having the highest height is formed.

In this manner, the height of the pedestal 140 may be adjusted according to the presence or absence of the irregularities 140e on the surface of the conductor layer 140a and the size of the irregularities 140e on the surface of the conductor layer 140a. In addition, by combining the adjustment based on the presence or absence of the irregularities 140e on the surface of the conductor layer 140a and the size of the irregularities 140e on the surface of the conductor layer 140a with the adjustment based on the width and the height of the conductor layer 140a, it is possible to realize the pedestals 140 having various heights. For example, when the irregularities 140e having a large size are provided on the surface of the narrow conductor layer 140a, the pedestal 140 having a lower height may be formed, as compared with a case where the irregularities 140e having a smaller size are provided, or a case where the irregularities 140e are not provided.

Sixth Embodiment

Here, a method of forming an electronic device will be described as a sixth embodiment.

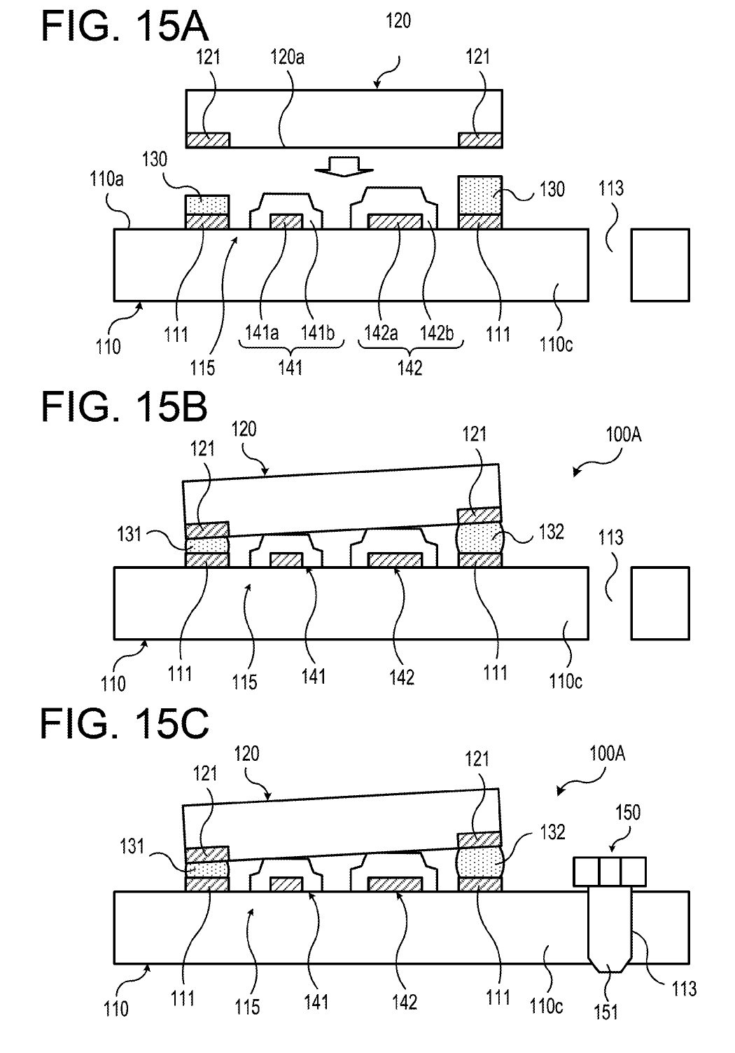

FIGS. 15A to 15C are views illustrating a first example of a method of forming an electronic device according to a sixth embodiment. FIGS. 15A to 15C schematically illustrate cross-sectional views of major parts of each process of forming an electronic device, respectively.

Here, formation of the electronic device 100A described in the second embodiment will be described by way of example. In the formation of the electronic device 100A, first, as illustrated in FIG. 15A, the printed circuit board 110 having the pedestal 141 and the pedestal 142 and the semiconductor device 120 to be mounted on the printed circuit board 110 are prepared.

The printed circuit board 110 having the pedestal 141 and the pedestal 142 is formed using, for example, the method described in the fifth embodiment. In this example, the printed circuit board 110 in which, inside the terminals 111, the pedestal 141 is provided at a position which is relatively far from the screw fastening hole 113 and the pedestal 142 having a height higher than that of the pedestal 141 is provided at a position which is relatively close to the screw fastening hole 113 is prepared. In addition, as the semiconductor device 120, a QFN type semiconductor device in which the terminals 121 are arranged along the edge is prepared.

As illustrated in FIG. 15A, as a bonding material, for example, a solder paste 130 is supplied onto the terminals 111 of the prepared printed circuit board 110. A greater amount of the solder paste 130 is supplied onto the terminal 111 provided at a position which is relatively close to the screw fastening hole 113 than onto the terminal 111 provided at a position which is relatively far from the screw fastening hole 113. The supply amount of the solder paste 130 onto each terminal 111 is set based on the heights of the solder bonding element 131 and the solder bonding element 132 formed to be described later. The supply of the solder paste 130 is performed by a method of printing the solder paste 130 using a metal mask which has an opening having a predetermined size and depth (thickness) at a position corresponding to the terminal 111 or a method of dropping the solder paste 130 onto the terminal 111 using a solder supply device such as, for example, a dispenser.

The printed circuit board 110 provided with the solder paste 130 and the prepared semiconductor device 120 are disposed such that the upper surface 110a and the lower surface 120a thereof face each other and the terminals 111 and the terminals 121 thereof are aligned with each other, as illustrated in FIG. 15A.

Next, the solder paste 130 is heated to a predetermined temperature at which the solder paste 130 melts, and the semiconductor device 120 is pressed against the printed circuit board 110 with a predetermined load.

By such heating and pressing, as illustrated in FIG. 15B, the terminals 121 of the semiconductor device 120 and the terminals 111 of the printed circuit board 110 are bonded to each other by the solder bonding element 131 and the solder bonding element 132 which are formed from the solder paste 130. Therefore, the electronic device 100A in which the semiconductor device 120 is electrically and mechanically connected onto the printed circuit board 110 by the solder bonding element 131 and the solder bonding element 132 is formed.

When the semiconductor device 120 is mounted on the printed circuit board 110 in this manner, since the pedestal 141 and the pedestal 142 are provided on the printed circuit board 110, a gap of a certain value or higher is formed between the printed circuit board 110 and the semiconductor device 120. Therefore, the solder bonding element 131 and the solder bonding element 132 having a height of a certain value or higher are formed. In addition, since the pedestal 141 and the pedestal 142 are provided on the printed circuit board 110 and since the amount of the solder paste 130 on the terminals 111 is adjusted according to a difference in the distance from the screw fastening hole 113, the semiconductor device 120 is bonded so as to be inclined with respect to the printed circuit board 110. That is, the semiconductor device 120 is obliquely bonded onto the printed circuit board 110 so that the solder bonding element 132 formed at a position which is relatively close to the screw fastening hole 113 is higher than the solder bonding element 131 formed at a position which is relatively far from the screw fastening hole 113. Therefore, the effect of alleviating the stress generated in the solder bonding element 131 and the solder bonding element 132 is enhanced and the lifespan of both the solder bonding element 131 and the solder bonding element 132 is prolonged.

As illustrated in FIG. 15C, the printed circuit board 110 of the formed electronic device 100A is fastened to, for example, a housing of an electronic apparatus in the screw fastening portion 150 as the screw 151 is inserted into the hole 113 formed in the printed circuit board 110. In the electronic device 100A, as described above, the solder bonding element 131 and the solder bonding element 132 are formed to have a height of a certain value or higher, and among them, the solder bonding element 132 which is relatively close to the screw fastening portion 150 is higher than the other one. Therefore, both the stresses generated in the solder bonding element 131 and the solder bonding element 132 by the screw fastening portion 150 as a stress generation source are effectively alleviated. Thus, the electronic device 100A having high bonding reliability in which the occurrence of a bonding failure due to the stress is suppressed is realized.

Here, although the formation of the electronic device 100A described in the second embodiment has been described by way of example, for example, the electronic device 100B described in the second embodiment or the electronic device 100E described in the fourth embodiment may also be formed according to the example illustrated in FIGS. 15A to 15C.

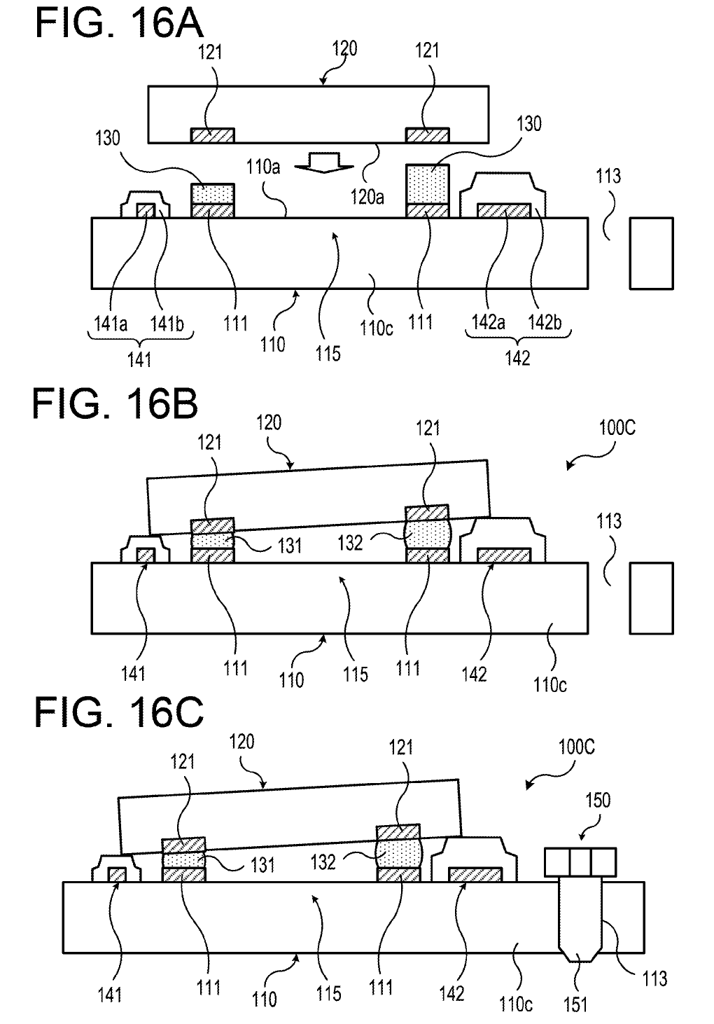

FIGS. 16A to 16C are views illustrating a second example of the method of forming the electronic device according to the sixth embodiment. FIGS. 16A to 16C schematically illustrate cross-sectional views of major parts of each process of forming the electronic device, respectively.

Here, formation of the electronic device 100C described in the third embodiment will be described by way of example. In the formation of the electronic device 100C, first, the printed circuit board 110 having the pedestal 141 and the pedestal 142 and the semiconductor device 120 are prepared, as illustrated in FIG. 16A.

The printed circuit board 110 having the pedestal 141 and the pedestal 142 is formed using, for example, the method described in the fifth embodiment. In this example, the printed circuit board 110 in which, outside the terminals 111, the pedestal 141 is provided at a position which is relatively far from the screw fastening hole 113 and the pedestal 142 having a height higher than that of the pedestal 141 is provided at a position which is relatively close to the screw fastening hole 113 is prepared. In addition, as the semiconductor device 120, an LGA type semiconductor device in which the terminals 121 are arranged along the edge at positions inside the edge is prepared.

As illustrated in FIG. 16A, the solder paste 130 is supplied as a bonding material onto the terminals 111 of the prepared printed circuit board 110. A greater amount of the solder paste 130 is supplied onto the terminal 111 provided at a position which is relatively close to the screw fastening hole 113 than onto the terminal 111 provided at a position which is relatively far from the screw fastening hole 113. The supply of the solder paste 130 is performed by, for example, printing using a metal mask, or dropping using a dispenser.

The printed circuit board 110 provided with the solder paste 130 and the prepared semiconductor device 120 are arranged so as to face each other as illustrated in FIG. 16A. Then, as illustrated in FIG. 16B, by heating and pressing, the terminals 121 of the semiconductor device 120 and the terminals 111 of the printed circuit board 110 are bonded to each other by the solder bonding element 131 and the solder bonding element 132 which are formed from the solder paste 130. Therefore, the electronic device 100C in which the semiconductor device 120 is electrically and mechanically connected onto the printed circuit board 110 by the solder bonding element 131 and the solder bonding element 132 is formed.

Since the pedestal 141 and the pedestal 142 are provided on the printed circuit board 110, a gap of a certain value or higher is secured between the printed circuit board 110 and the semiconductor device 120, so that the solder bonding element 131 and the solder bonding element 132 having a height of a certain value or higher are formed. In addition, by the pedestal 141 and the pedestal 142 on the printed circuit board 110 and adjustment in the amount of the solder paste 130 according to the distance from the screw fastening hole 113, the semiconductor device 120 is bonded so as to be inclined with respect to the printed circuit board 110 so that one side thereof close to the hole 113 is higher than the other side. Therefore, the effect of alleviating the stress generated in the solder bonding element 131 and the solder bonding element 132 is enhanced, and the lifespan of both the solder bonding element 131 and the solder bonding element 132 is prolonged.

As illustrated in FIG. 16C, the printed circuit board 110 of the formed electronic device 100 C is fastened to, for example, a housing of an electronic apparatus in the screw fastening portion 150 as the screw 151 is inserted into the hole 113 formed in the printed circuit board 110. In the electronic device 100C, as described above, the solder bonding element 131 and the solder bonding element 132 are formed to have a height of a certain value or higher, and among them, the solder bonding element 132 which is relatively close to the screw fastening portion 150 is higher than the other one. Therefore, both the stresses generated in the solder bonding element 131 and the solder bonding element 132 by the screw fastening portion 150 as a stress generation source are effectively alleviated. Thus, the electronic device 100C having high bonding reliability in which the occurrence of a bonding failure due to the stress is suppressed is realized.

Here, the formation of the electronic device 100C described in the third embodiment has been described by way of example, but, for example, the electronic device 100D described in the third embodiment may also be formed according to the example illustrated in FIGS. 16A to 16C.

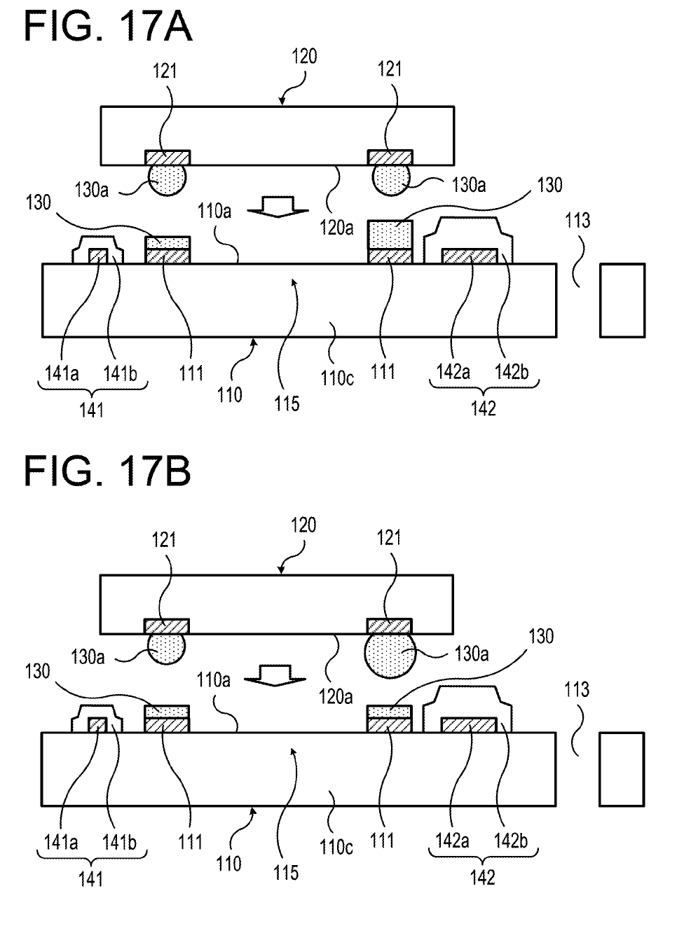

FIGS. 17A and 17B are views illustrating a third example of the method of forming the electronic device according to the sixth embodiment. FIGS. 17A and 17B schematically illustrate cross-sectional views of major parts of one process of forming the electronic device, respectively.

The semiconductor device 120 to be mounted on the printed circuit board 110 may be a ball grid array (BGA) type semiconductor device in which a bump, for example, a solder ball 130a as illustrated in FIGS. 17A and 17B is mounted on the terminal 121.

For example, in the example illustrated in FIG. 17A, the semiconductor device 120 in which the solder balls 130a having the same size or substantially the same size are mounted on different terminals 121 is used. For example, the semiconductor device 120 faces the printed circuit board 110 in which the pedestal 141 and the pedestal 142 are provided outside the terminals 111 such that one of them which is closer to the hole 113 is higher than the other one and on which the solder paste 130 is provided such that a greater amount of the solder paste 130 is provided on the terminal 111 which is closer to the hole 113. Then, according to the above example, the semiconductor device 120 is mounted on the printed circuit board 110, and the printed circuit board 110 is fastened to, for example, a housing by the screw 151 inserted through the hole 113.

In the example of FIG. 17A, the amount of the solder paste 130 to be supplied onto the terminals 111 of the printed circuit board 110 is adjusted with respect to the semiconductor device 120 on which the solder balls 130a having the same size or substantially the same size are mounted. Therefore, solder bonding elements having a height of a certain value or higher are formed from the solder paste 130 and the solder balls 130a so that the solder bonding element which is closer to the hole 113 (the screw fastening portion 150) is higher. The semiconductor device 120 and the printed circuit board 110 are electrically and mechanically bonded to each other by the solder bonding elements. Thus, an electronic device having high bonding reliability similar to the above is realized.

In addition, in the example illustrated in FIG. 17B, the semiconductor device 120 in which the solder balls 130a having different sizes are mounted on different terminals 121 is used. Specifically, the semiconductor device 120 in which the solder ball 130a having a larger size is mounted on the terminal 121 corresponding to the terminal 111 which is closer to the hole 113 in the printed circuit board 110 is used. For example, the semiconductor device 120 faces the printed circuit board in which the pedestal 141 and the pedestal 142 are provided outside the terminals 111 such that one of them which is closer to the hole 113 is higher than the other one and a certain amount of the solder paste 130 is provided on the terminals 111. Then, according to the above example, the semiconductor device 120 is mounted on the printed circuit board 110, and the printed circuit board 110 is fastened to, for example, the housing by the screw 151 inserted through the hole 113.

In the example of FIG. 17B, the sizes of the solder balls 130a mounted on the terminals 121 of the semiconductor device 120 are adjusted with respect to the printed circuit board 110 to which a certain amount of the solder paste 130 is supplied onto the terminals 111. Therefore, solder bonding elements having a height of a certain value or higher are formed from the solder paste 130 and the solder balls 130a such that the solder bonding element which is relatively closer to the hole 113 (the screw fastening portion 150) is higher. The semiconductor device 120 and the printed circuit board 110 are electrically and mechanically bonded to each other by the solder bonding elements. Thus, an electronic device having high bonding reliability similar to the above is realized.

In FIGS. 17A and 17B, the mounting of the semiconductor device 120 on the printed circuit board 110 in which the pedestal 141 and the pedestal 142 are provided outside the terminals 111 has been described by way of example. In addition, the mounting of the semiconductor device 120 on the printed circuit board 110 in which the pedestal 141 and the pedestal 142 are provided inside the terminals 111 may also be performed according to the example of FIGS. 17A and 17B.

Seventh Embodiment

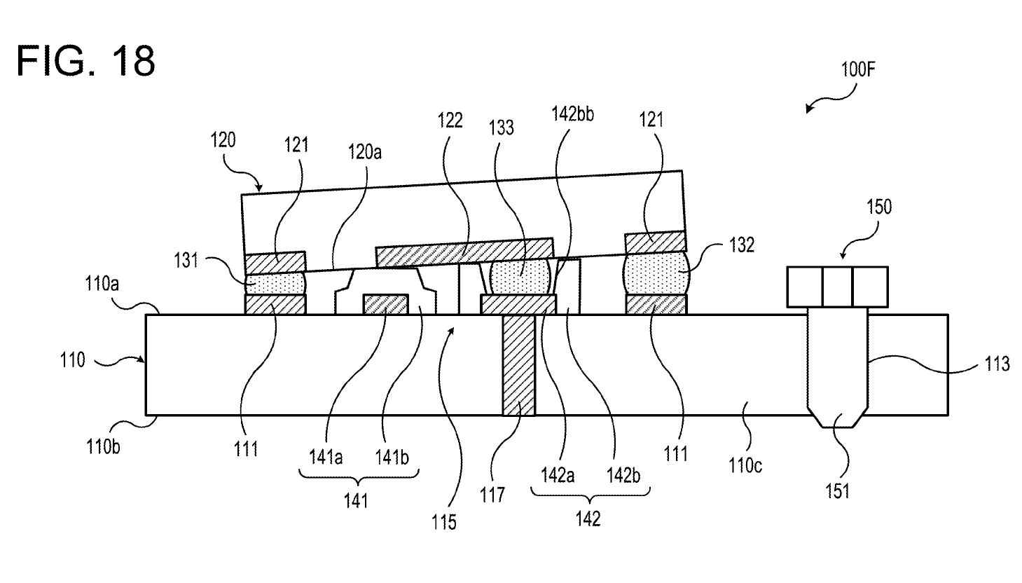

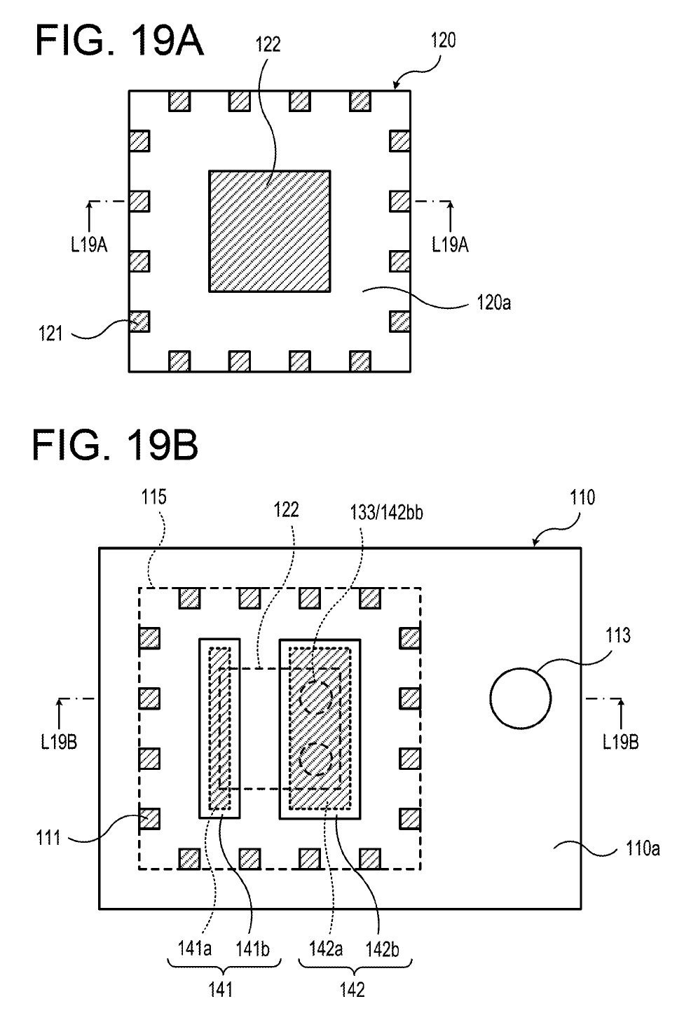

FIGS. 18, 19A and 19B are views illustrating an example of an electronic device according to a seventh embodiment. FIG. 18 schematically illustrates a cross-sectional view of major parts of an example of the electronic device. FIG. 19A schematically illustrates a plan view of major parts of the semiconductor device viewed from the terminal surface side, and FIG. 19B illustrates a plan view of major parts of the printed circuit board viewed from the terminal surface side. In addition, FIG. 18 is a view corresponding to the position of the L19A-L19A cross section of FIG. 19A and the position of the L19B-L19B cross section of FIG. 19B.

In the electronic device 100F illustrated in FIG. 18, as the semiconductor device 120, as illustrated in FIGS. 18 and 19A, a QFN-type semiconductor device in which the terminals 121 are arranged along the edge of the lower surface 120a which faces the printed circuit board 110 is used. In addition, in the QFN type semiconductor device 120, as illustrated in FIGS. 18 and 19A, a pad 122 is provided on the center portion of the lower surface 120a. The pad 122 may be a pad for fixing the semiconductor device 120 to the printed circuit board 110, a pad for dissipating heat from the semiconductor device 120 to the printed circuit board 110, or a GND connection pad for grounding the semiconductor device 120 on the printed circuit board 110. In addition, the pad 122 may be a signal transmission pad which transmits a signal between the semiconductor device 120 and the printed circuit board 110.

In the electronic device 100F, as illustrated in FIGS. 18 and 19B, the pad 122 of the semiconductor device 120 is bonded to the conductor layer 141a of the pedestal 141 and/or the conductor layer 142a of the pedestal 142 on the printed circuit board 110, in this example, to the conductor layer 142a of the pedestal 142 by a solder bonding element 133. For example, an opening 142bb is provided in a portion of the insulating layer 142b covering the conductor layer 142a, and a portion of the conductor layer 142a exposed from the opening 142bb is bonded to the pad 122 by the solder bonding element 133. As illustrated in FIG. 18, the printed circuit board 110 may be provided with a conductor pattern 117, for example, a thermal via, a GND via, or a signal via, which is connected to the conductor layer 142a bonded to the pad 122 of the semiconductor device 120 by the solder bonding element 133.

The electronic device 100F differs from the electronic device 100A in that it has such a configuration. Similarly to the electronic device 100F, the conductor layer 142a of the pedestal 142 (and/or the conductor layer 141a of the pedestal 141) may be used for the fixing, heat dissipation, GND connection, or signal transmission of the semiconductor device 120.

In addition, a connection structure similar to that of the electronic device 100F may be adopted so long as, for example, a fixing, heat radiation, GND connection, or signal transmission pad is provided on the center portion of the lower surface 120a of the semiconductor device 120 and a pedestal including a conductor layer is formed on the printed circuit board 110A so as to correspond to the pad.

Eighth Embodiment

In the above description, an example in which the pedestal 141 and the pedestal 142 are provided on the printed circuit board 110 has been described, but the pedestal 141 and the pedestal 142 may be provided on the semiconductor device 120 side. Such an example will be described as an eighth embodiment.

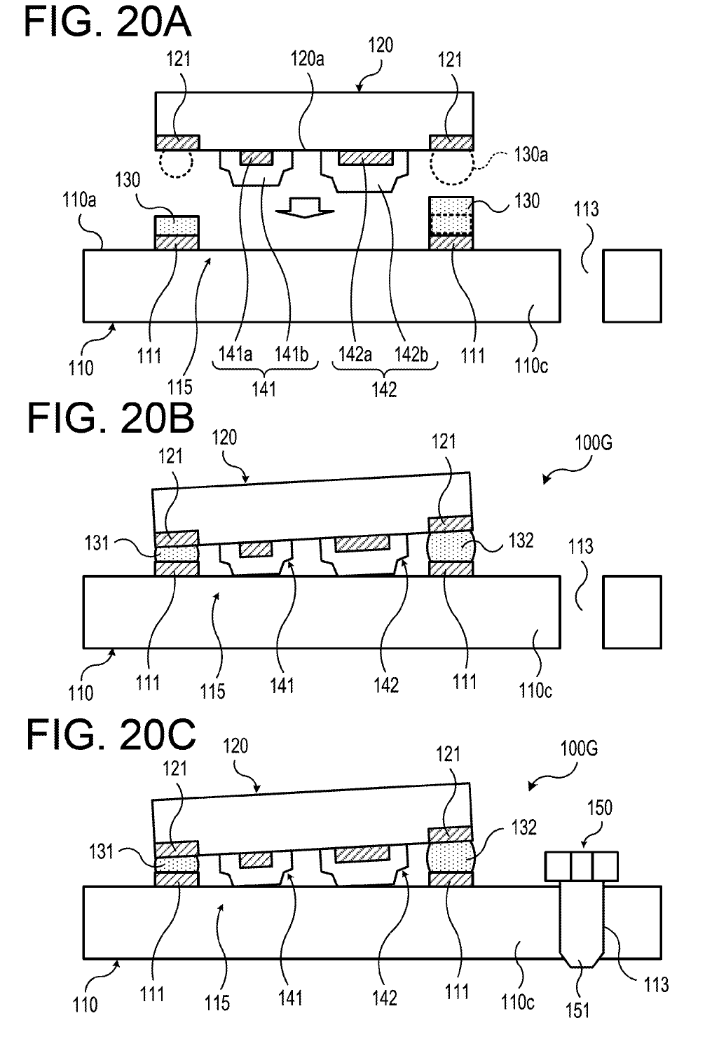

FIGS. 20A to 20C are views illustrating an example of a method of forming an electronic device according to an eighth embodiment. FIGS. 20A to 20C schematically illustrate cross-sectional views of major parts of each process of forming the electronic device, respectively.

In this example, as illustrated in FIG. 20A, the semiconductor device 120 in which the pedestal 141 and the pedestal 142 are provided inside the terminals 121 and the printed circuit board 110 which is provided with the terminals 111 at positions corresponding to the terminals 121 are prepared. The formation of the pedestal 141 and the pedestal 142 with respect to the semiconductor device 120 may be performed according to the example of the method as described above in the fifth embodiment.

The solder paste 130 (indicated by a solid line) is supplied onto the terminals 111 of the printed circuit board 110 such that the amount of the solder paste on the terminal 111 provided at a position which is relatively close to the screw fastening hole 113 is greater than that on the terminal 111 provided at a position which is relatively far from the screw fastening hole 113. Alternatively, according to the example of FIG. 17B, a certain amount of the solder paste 130 (illustrated by a dotted line) is supplied onto the terminals 111 of the printed circuit board 110, and the solder balls 130a (illustrated by a dotted line) having different sizes are mounted on the terminals 121 of the semiconductor device 120.

The printed circuit board 110 provided with the solder paste 130 and the semiconductor device 120 provided with the pedestal 141 and the pedestal 142 are arranged to face each other as illustrated in FIG. 20A. Then, as illustrated in FIG. 20B, by heating and pressing, the terminals 121 of the semiconductor device 120 and the terminals 111 of the printed circuit board 110 are bonded to each other by the solder bonding element 131 and the solder bonding element 132 which are formed of the solder paste 130 and/or the solder balls 130a. Therefore, the electronic device 100G is formed in which the semiconductor device 120 is electrically and mechanically connected to the printed circuit board 110 by the solder bonding element 131 and the solder bonding element 132.

In this example, since the pedestal 141 and the pedestal 142 are provided on the semiconductor device 120, a gap of a certain value or higher is secured between the printed circuit board 110 and the semiconductor device 120, and the solder bonding element 131 and the solder bonding element 132 having a height of a certain value or higher are formed. In addition, by adjusting the pedestal 141 and the pedestal 142 on the semiconductor device 120, and the amount of the solder paste 130 or the size of the solder ball 130a according to the distance from the screw fastening hole 113, the semiconductor device 120 is bonded so as to be inclined with respect to the printed circuit board 110 so that one side thereof close to the hole 113 is higher than the other side. Therefore, the effect of alleviating the stress generated in the solder bonding element 131 and the solder bonding element 132 is enhanced, and the lifespan of both the solder bonding element 131 and the solder bonding element 132 is prolonged.

As illustrated in FIG. 20C, the printed circuit board 110 of the formed electronic device 100G is fastened to, for example, a housing of an electronic apparatus in the screw fastening portion 150 as the screw 151 is inserted into the hole 113 formed in the printed circuit board 110. In the electronic device 100G, as described above, the solder bonding element 131 and the solder bonding element 132 are formed to have a height of a certain value or higher, and among them, the solder bonding element 132 which is relatively close to the screw fastening portion 150 is higher than the other one. Therefore, both the stresses generated in the solder bonding element 131 and the solder bonding element 132 by the screw fastening portion 150 as a stress generation source are effectively alleviated, and the occurrence of a bonding failure due to the stresses is suppressed.

In this way, even in a case where the pedestal 141 and the pedestal 142 are provided on the semiconductor device 120 side, it is possible to realize the electronic device 100G having high bonding reliability.

Ninth Embodiment

The electronic devices 1A, 1B, 100A, 100B, 100C, 100D, 100E, 100F, and 100G, for example, as described above may be mounted on various electronic apparatuses. For example, the electronic devices may be mounted in various electronic apparatuses such as a computer (e.g., a personal computer, a super computer, or a server), a smart phone, a mobile phone, a tablet terminal, a sensor, a camera, an audio apparatus, a measuring device, an inspection device, and a manufacturing device.

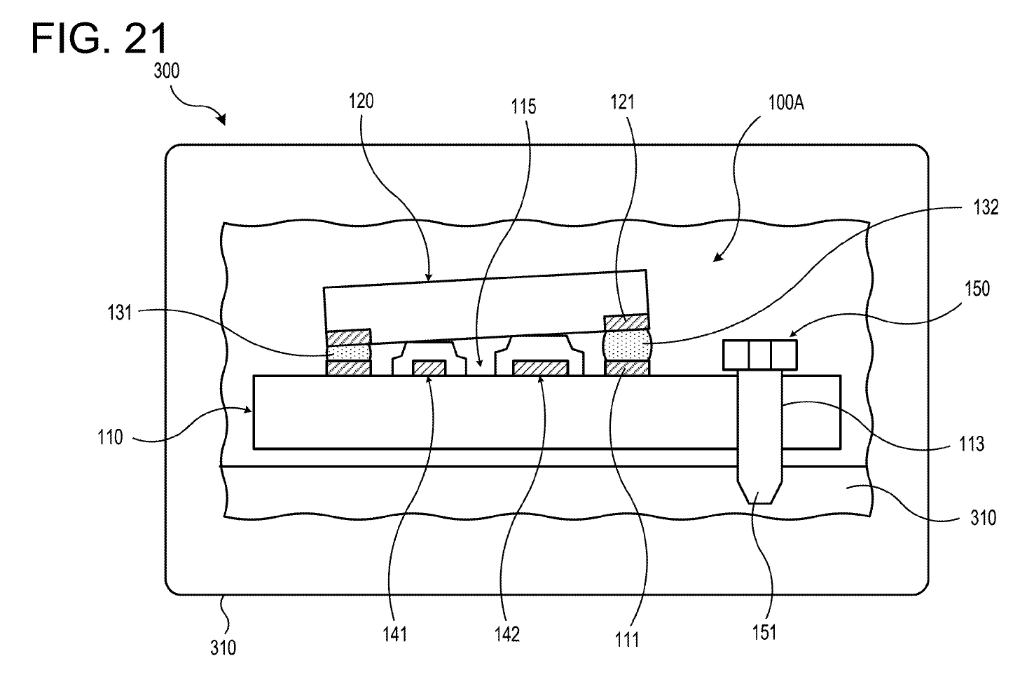

FIG. 21 is a view for explaining an electronic apparatus according to a ninth embodiment. FIG. 21 schematically illustrates the electronic apparatus. As illustrated in FIG. 21, for example, the electronic device 100A (FIG. 2) as described in the second embodiment is mounted (built-in) inside a housing 310 of any of various electronic apparatuses 300.

The electronic device 100A includes the printed circuit board 110, the semiconductor device 120 mounted on the printed circuit board 110, and the pedestal 141, the pedestal 142, the solder bonding element 131 and the solder bonding element 132 which are provided between the printed circuit board 110 and the semiconductor device 120 such that one of them closer to the hole 113 is higher. The electronic device 100A is fastened to the housing 310 in the screw fastening portion 150 to thereby be mounted on the electronic apparatus 300 as the screw 151 is inserted through the hole 113 in the printed circuit board 110.

In addition, in addition to the semiconductor device 120 supported by the pedestal 141 and the pedestal 142, another semiconductor device supported by pedestals which are adjusted to have different heights according to a difference in the distance to the screw fastening portion 150 may be mounted on the printed circuit board 110. In addition, a semiconductor device not supported by a pedestal or various chip components such as, for example, a chip capacitor may be mounted on the printed circuit board 110.

In the electronic device 100A, the pedestal 141 and the pedestal 142 are provided between the printed circuit board 110 and the semiconductor device 120, and a height of a certain value or higher is secured for the solder bonding element 131 and the solder bonding element 132. Therefore, the effect of alleviating the stress in the solder bonding element 131 and the solder bonding element 132 is enhanced, and the lifespan of both the solder bonding element 131 and the solder bonding element 132 is prolonged. In addition, in the electronic device 100A, the height of the solder bonding element 132 which is close to the screw fastening portion 150 and generates relatively large stress is higher than the height of the solder bonding element 131 which is far from the screw fastening portion 150 and generates relatively small stress. Therefore, the lifespan of both the solder bonding element 131 and the solder bonding element 132 is prolonged. The electronic device 100A having high bonding reliability between the printed circuit board 110 and the semiconductor device 120 is realized and a high performance electronic device 300 in which such an electronic device 100A is mounted is realized.

Here, the electronic apparatus 300 in which the electronic device 100A is mounted has been exemplified, but the electronic devices 1A, 1B, 100B, 100C, 100D, 100E, 100F, and 100G, for example, may also be mounted in various electronic devices.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a substrate;
an electronic component provided in a first area of the substrate;
a spacer provided between the substrate and the electronic component so as to come into contact with the substrate and the electronic component;
a first bonding element provided between the substrate and the electronic component so as to bond the substrate and the electronic component;
a second bonding element provided between the substrate and the electronic component so as to bond the substrate and the electronic component, the second bonding element having a height higher than a height of the first bonding element; and
a stress generation source provided outside the first area of the substrate to generate a stress in the first area of the substrate, the stress generation source being located closer to the second bonding element than to the first bonding element.

2. The electronic device according to claim 1,
wherein the spacer is located at an inside as compared to the first bonding element and the second bonding element, in the first area.

3. The electronic device according to claim 1,
wherein the spacer is located at an outside as compared to the first bonding element and the second bonding element, in the first area.

4. The electronic device according to claim 1,
wherein the spacer includes a conductor layer electrically separated from the first bonding element and the second bonding element.

5. The electronic device according to claim 1,
wherein the spacer includes a conductor layer that electrically interconnects the substrate and the electronic component.

6. The electronic device according to claim 1,
wherein the spacer is configured to include:
a first spacer, and
a second spacer located closer to the stress generation source than the first spacer, the second spacer having a height higher than a height of the first spacer.

7. The electronic device according to claim 6,
wherein the first spacer is configured to include a first insulating layer provided on the substrate, and
wherein the second spacer includes: a second conductor layer provided on the substrate, and a second insulating layer provided on the substrate and configured to cover the second conductor layer.

8. The electronic device according to claim 6,
wherein the first spacer includes:
a first conductor layer provided on the substrate; and
a first insulating layer provided on the substrate and configured to cover the first conductor, and
wherein the second spacer includes:
a second conductor layer provided on the substrate and configured to have a size larger than a size of the first conductor layer, and
a second insulating layer provided on the substrate and configured to cover the second conductor layer.

9. The electronic device according to claim 6,
wherein the first spacer includes:
a first conductor layer provided on the substrate and configured to have irregularities on a surface thereof; and
a first insulating layer provided on the substrate and configured to cover the first conductor layer, and
wherein the second spacer includes:
a second conductor layer provided on the substrate and configured to have smaller irregularities on a surface thereof than irregularities on the surface of the first conductor layer; and
a second insulating layer provided on the substrate and configured to cover the second conductor layer.

10. A substrate comprising:
a spacer provided in a first area where an electronic component is to be mounted with a height at which the spacer is in contact with the electronic component;
a first bonding material provided in the first area;
a second bonding material provided in the first area and configured to have a volume larger than a volume of the first bonding material; and
a stress generation source provided outside the first area to generate a stress in the first area, the stress generation source being located closer to the second bonding material than to the first bonding material.

11. An electronic component comprising:
a spacer provided on a first surface that faces a first area of a substrate to be mounted with a height at which the spacer is in contact with the first area when mounted in the first area;
a first bonding material provided on the first surface; and
a second bonding material provided on the first surface and configured to have a volume larger than a volume of the first bonding material,
wherein the second bonding material is provided at a position closer to a stress generation source than the first bonding material, the stress generation source being provided in the substrate and is configured to generate a stress in the first area.
